(19) United States
(12) Patent Application Publication
(10) Pub. No.: US 2025/0248083 A1
(43) Pub. Date: Jul. 31, 2025

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: JUSEONG MIN, SUWON-SI (KR); JAE-BOK BAEK, SUWON-SI (KR); JEEHOON HAN, SUWON-SI (KR)

(21) Appl. No.: 18/916,152

(22) Filed: Oct. 15, 2024

(30) Foreign Application Priority Data
Jan. 29, 2024 (KR) 10-2024-0013290

(51) Int. Cl. H01L 29/06; H01L 27/092; H01L 29/417; H10B 12/00

(52) U.S. Cl. CPC H10D 62/115; H10B 12/485; H10B 12/50; H10D 64/257; H10D 84/85; H10B 12/05

(57) ABSTRACT

A semiconductor device includes a semiconductor substrate, a transistor, a first interlayer insulation layer, a plurality of contacts, and a separation insulator. The transistor is on the semiconductor substrate. The transistor includes a gate structure, and source and drain regions. The first interlayer insulation layer is on the gate structure and the source and drain regions of the transistor. The plurality of contacts pass through the first interlayer insulation layer and are electrically connected to the source and drain regions of the transistor. The separation insulator passes through the first interlayer insulation layer and extends to an inside of the semiconductor substrate at a boundary of the transistor. The plurality of contacts include an adjacent contact that is adjacent to the separation insulator and is spaced apart from the gate structure. The first interlayer insulation layer is interposed between the adjacent contact and the gate structure.

### CROSS-REFERENCE TO RELATED APPLICATION

This patent application claims priority under 35 U.S.C. § 119 to Korean Patent Application No. 10-2024-0013290 filed in the Korean Intellectual Property Office on Jan. 29, 2024, the disclosure of which is incorporated by reference in its entirety herein.

### (a) Technical Field

The present disclosure relates to a semiconductor device and an electronic system including the same.

### (b) Discussion of Related Art

A semiconductor device may have a small size while performing various functions, and is thus widely used in various electronic industries. The integration degree of the semiconductor device may be increased by reducing a distance between circuit elements (e.g., transistors) included in the semiconductor device. A shallow trench isolation (STI) region may be present between adjacent transistors to prevent electrical interference and leakage, which can negatively affect performance and reliability. However, the STI region needs to be a certain distance away from the transistors to prevent it from affecting the electrical characteristics of the transistors. Thus, there is a limit to how much this distance can be reduced.

Accordingly, there is a need for a semiconductor device that allows transistors to be brought closer together to increase the integration degree without reducing performance.

### SUMMARY

The present disclosure attempts to provide a semiconductor device with a reduced size and a higher integration degree and an electronic system including the same.

A semiconductor device according to an embodiment includes a semiconductor substrate, a transistor, a first interlayer insulation layer, a plurality of contacts, and a separation insulator. The transistor is disposed on the semiconductor substrate. The transistor includes a gate structure, and source and drain regions at respective sides of the gate structure. The first interlayer insulation layer is disposed on the gate structure and the source and drain regions of the transistor. The plurality of contacts pass through the first interlayer insulation layer. Each of the contacts is electrically connected to a corresponding one of the source and drain regions. The separation insulator passes through the first interlayer insulation layer and extends to an inside of the semiconductor substrate at a boundary of the transistor. The plurality of contacts include an adjacent contact that is adjacent to the separation insulator and is spaced apart from the gate structure. The first interlayer insulation layer is interposed between the adjacent contact and the gate structure.

A semiconductor device according to an embodiment includes a semiconductor substrate, first and second transistors, a device separator, a first interlayer insulation layer, and a separation insulator. The first and second transistors are disposed on the semiconductor substrate. Each of the transistors includes a gate structure, and source and drain regions at respective sides of the gate structure. The device separator is disposed in part of the semiconductor substrate. The first interlayer insulation layer is disposed on the gate structure and the source and drain regions of each of the transistors, and the device separator. The separation insulator passes through the first interlayer insulation layer and extends to an inside of the semiconductor substrate. The second transistor has an operating voltage higher than an operating voltage of the first transistor. The device separator and the separation insulator are disposed at a boundary of the first transistor, and the device separator is disposed at a boundary of the second transistor.

An electronic system according to an embodiment includes a main substrate, a semiconductor device disposed on the main substrate, and a controller electrically disposed on the main substrate to be connected to the semiconductor device. The semiconductor device includes a semiconductor substrate, a transistor, a first interlayer insulation layer, a plurality of contacts, and a separation insulator. The transistor is disposed on the semiconductor substrate. The transistor includes a gate structure, and source and drain regions at respective sides of the gate structure. The first interlayer insulation layer is disposed on the gate structure and the source and drain regions of the transistor. The plurality of contacts pass through the first interlayer insulation layer. Each of the contacts is electrically connected to a corresponding one of the source and drain regions of the transistor. The separation insulator passes through the first interlayer insulation layer and extends to an inside of the semiconductor substrate at a boundary of the transistor. The plurality of contacts include an adjacent contact that is adjacent to the separation insulator and spaced apart from the gate structure. The first interlayer insulation layer is interposed between the adjacent contact and the gate structure.

According to an embodiment, a plurality of contacts (e.g., an adjacent contact) may be formed by a self-alignment through using a separation insulator and thus a margin for forming the plurality of contacts may be reduced. Accordingly, a distance between the plurality of transistors may be reduced, and thus, a size of a circuit region or a semiconductor device may be reduced and an integration degree may be increased.

### BRIEF DESCRIPTION OF THE DRAWINGS

FIG. 1 is a partial cross-sectional view schematically illustrating a semiconductor device according to an embodiment.

FIG. 2 is an enlarged cross-sectional view illustrating an example of a channel structure included in the semiconductor device illustrated in FIG. 1.

FIG. 3 is a cross-sectional view schematically illustrating a circuit region included in the semiconductor device illustrated in FIG. 1.

FIG. 4 is a partial plan view schematically illustrating the circuit region included in the semiconductor device illustrated in FIG. 1.

FIG. 5 is a schematic cross-sectional view taken along line B-B′ and line C-C′ of FIG. 4.

FIG. 6 to FIG. 13 are cross-sectional views illustrating a manufacturing method of a semiconductor device according to an embodiment.

FIG. 14 is a partial cross-sectional view schematically illustrating a circuit region included in a semiconductor device according to an embodiment.

FIG. 15 is a partial cross-sectional view schematically illustrating a circuit region included in a semiconductor device according to an embodiment.

FIG. 16 is a cross-sectional view schematically illustrating a semiconductor device according to an embodiment.

FIG. 17 is a view schematically illustrating an electronic system including a semiconductor device according to an embodiment.

FIG. 18 is a view schematically illustrating an electronic system including a semiconductor device according to an embodiment.

FIG. 19 is a perspective view schematically illustrating a semiconductor package including a semiconductor device according to an embodiment.

FIG. 20 is a perspective view schematically illustrating a semiconductor package including a semiconductor device according to an embodiment.

### DETAILED DESCRIPTION

Embodiments of the present disclosure will be described more fully hereinafter with reference to the accompanying drawings for those skilled in the art to which the present disclosure pertains to practice the present disclosure. However, the present disclosure may be implemented in various different forms and is not limited to the embodiment provided herein.

The same or similar components are denoted by the same reference numeral throughout the present specification.

While certain sizes and thicknesses of portions, regions, members, units, layers, films, etc. illustrated in the accompanying drawings are illustrated for a better understanding and convenience of explanation, the present disclosure is not limited to the illustrated sizes and thicknesses.

It will be understood that when a component such as a layer, film, region, or substrate is referred to as being “on” another component, it may be directly on other component or an intervening component may also be present.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate when a cross-section taken along a vertical direction is viewed from a side.

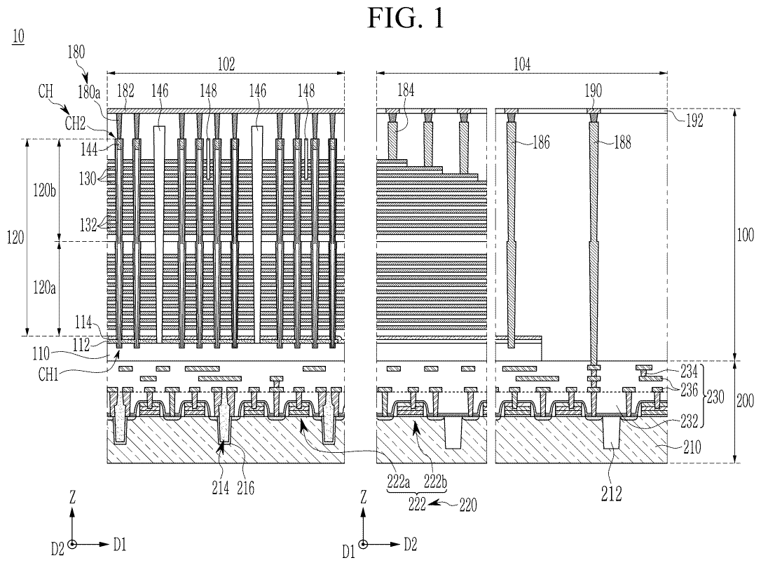

Hereinafter, with reference to FIG. 1 to FIG. 13, a semiconductor device and a manufacturing method of the same according to an embodiment will be described in detail.

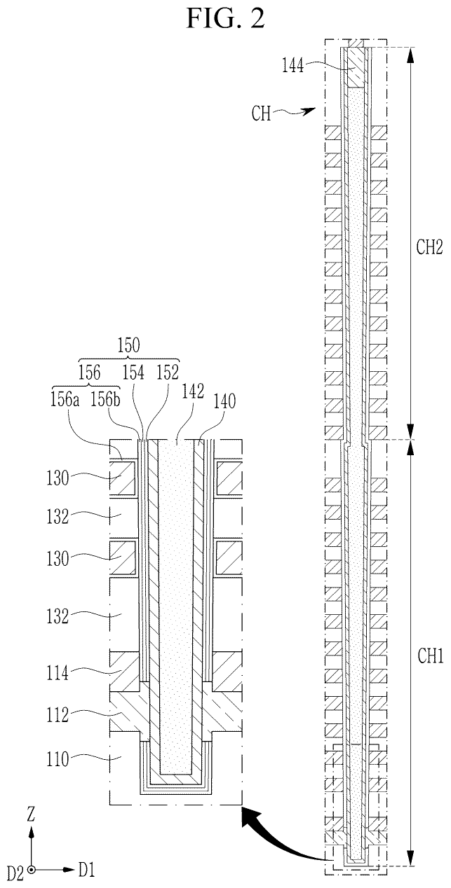

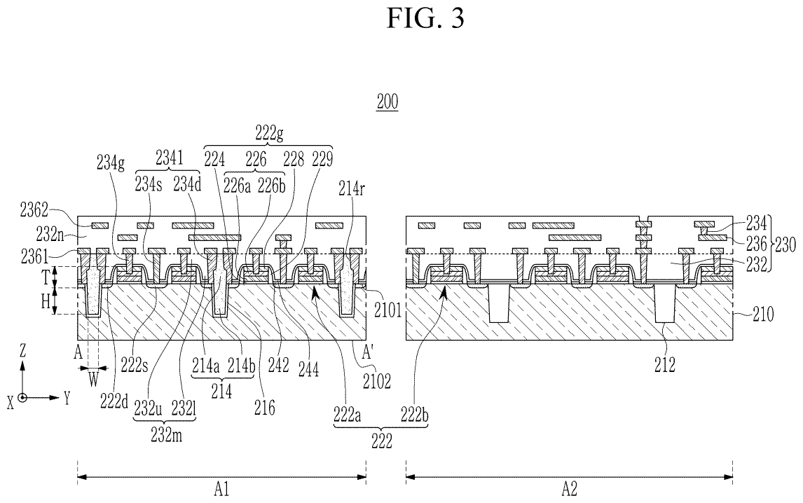

FIG. 1 is a partial cross-sectional view schematically illustrating a semiconductor device according to an embodiment. FIG. 2 is an enlarged cross-sectional view illustrating an example of a channel structure included in the semiconductor device illustrated in FIG. 1. In FIG. 1, it is illustrated as an example that a horizontal axis in a cell array region 102 of a cell region 100 is parallel to a transverse direction D1 that is transverse to (e.g., perpendicular to) an extension direction D2 of a gate line 130, and a horizontal axis in a connection region 104 of the cell region 100 is parallel to the extension direction of the gate line 130. FIG. 1 illustrates a cross-sectional view of a circuit region 200 where a gate structure 222g (refer to FIG. 3), and source and drain regions 222s and 222d (refer to FIG. 3) are positioned together regardless of the extension direction D2 of the gate line 130.

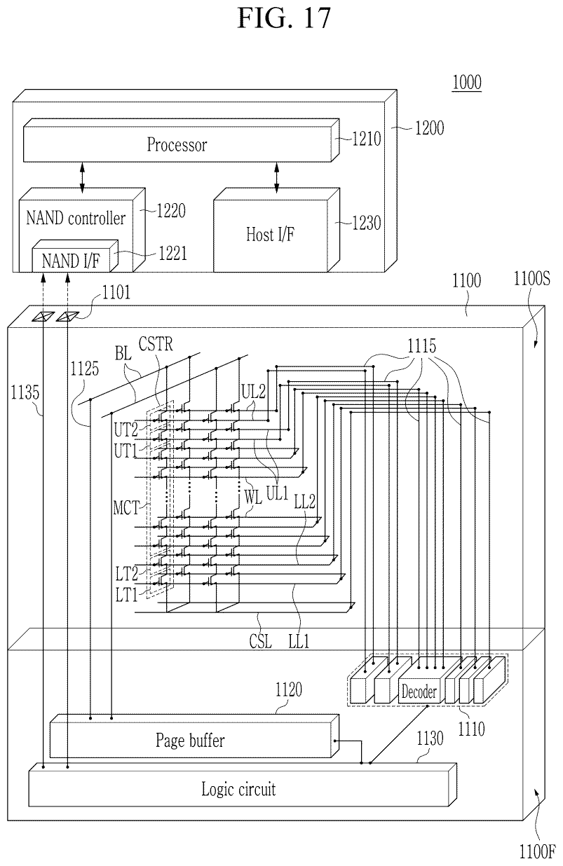

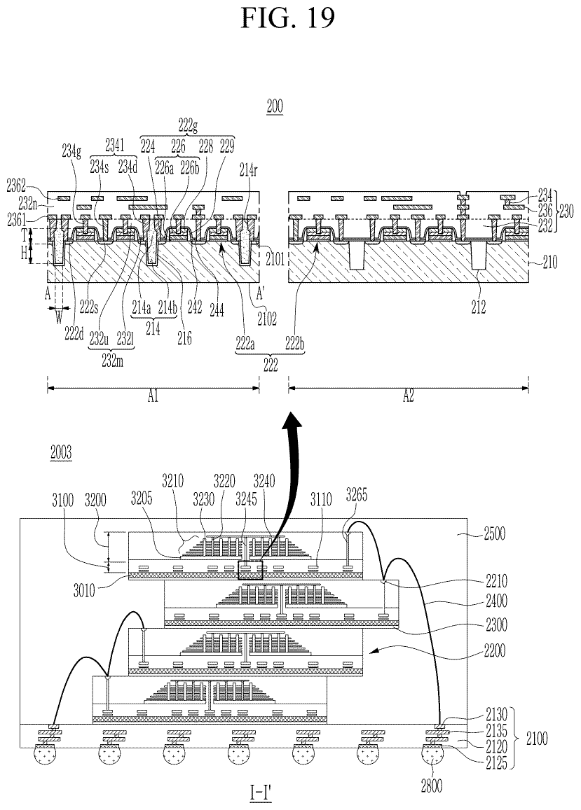

Referring to FIG. 1 and FIG. 2, a semiconductor device 10 according to an embodiment includes a cell region 100 including a memory cell structure and a circuit region 200 including a peripheral circuit structure controlling an operation of the memory cell structure. For example, the circuit region 200 and the cell region 100 may correspond to a first structure 1100F and a second structure 1100S of a semiconductor device 1100 included in an electronic system 1000 illustrated in FIG. 17, respectively. For example, the circuit region 200 and the cell region 100 may be portions including a first structure 3100 and a second structure 3200 of a semiconductor chip 2200 illustrated in FIG. 19, respectively.

In an embodiment, the circuit region 200 includes the peripheral circuit structure disposed on a first substrate 210, and the cell region 100 includes a gate stacking structure 120 and a channel structure CH disposed on a second substrate 110 as the memory cell structure. In an embodiment, the circuit region 200 includes a first wiring portion 230, and the cell region 100 includes a second wiring portion 180 electrically connected to the memory cell structure.

In an embodiment, the cell region 100 is disposed on the circuit region 200. For example, the cell region 100 may be stacked on top of the circuit region 200. Accordingly, an area corresponding to the circuit region 200 does not need to be secured separately from the cell region 100. Therefore, an area of the semiconductor device 10 may be reduced. However, the embodiments are not limited thereto. For example, the circuit region 200 may be disposed next to the cell region 100.

In an embodiment, the cell region 100 includes a cell array region 102 and a connection region 104. The gate stacking structure 120 and the channel structure CH may be disposed on the second substrate 110 in the cell array region 102. A structure that connects the gate stacking structure 120 and/or the channel structure CH in the cell array region 102 to the circuit region 200 or an external circuit may be disposed in the cell array region 102 and/or the connection region 104.

In an embodiment, the second substrate 110 includes a semiconductor layer including a semiconductor material. For example, the second substrate 110 may be a semiconductor substrate including or formed of a semiconductor material or may be a semiconductor substrate in which a semiconductor layer is disposed on a base substrate. For example, the second substrate 110 may include or be formed of silicon, germanium, silicon-germanium, silicon on insulator (SOI) or a germanium on insulator (GOI). The semiconductor layer included in the second substrate 110 may be doped with a p-type dopant or an n-type dopant. The p-type dopant may include boron (B) or gallium (Ga), and the n-type dopant may include phosphorus (P) or arsenic (As). However, the embodiments are not limited to a material of the second substrate 110 or a conductive type of the dopant doped in the semiconductor layer.

In the cell array region 102, the gate stacking structure 120 and the channel structure CH may be positioned. The gate stacking structure 120 may include cell insulation layers 132 and gate lines 130 alternately stacked on a first surface (e.g., a front surface or an upper surface) of the second substrate 110. The channel structure CH may extend in a direction crossing the second substrate 110 (a Z-axis direction in the drawings) while passing through or penetrating the gate stacking structure 120.

In an embodiment, horizontal conductive layers 112 and 114 are disposed between the second substrate 110 and the gate stacking structure 120 in the cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 disposed sequentially on the second substrate 110. The first horizontal conductive layer 112 may serve as part of a common source line of the semiconductor device 10. For example, the first horizontal conductive layer 112 combined with the second substrate 110 may serve as the common source line.

The first and the second horizontal conductive layers 112 and 114 may include or be formed of a semiconductor material (e.g., polycrystalline silicon). For example, the first horizontal conductive layer 112 may include or be formed of a polycrystalline silicon layer including a dopant. However, the embodiments are not limited thereto. In an embodiment, the second horizontal conductive layer 114 includes or is formed of a material (e.g., an insulating material) different from a material of the first horizontal conductive layer 112. In another embodiment, the second horizontal conductive layer 114 is omitted.

The gate stacking structure 120 may be disposed on the second substrate 110 (e.g., on the first and the second horizontal conductive layers 112 and 114 on the second substrate 110). The gate stacking structure 120 may include cell insulation layers 132 and gate lines 130 alternately stacked to each other.

The gate line 130 may include any of various conductive materials. For example, the gate line 130 may include or be formed of a metal material (e.g., tungsten (W), copper (Cu), aluminum (AI), or so on), polycrystalline silicon, metal nitride (e.g., titanium nitride (TiN) or tantalum nitride (TaN)). As illustrated in an enlarged view of FIG. 2, a partial portion of a blocking layer 156 (e.g., a first blocking layer 156a) including or being formed of an insulating material may be disposed outside the gate line 130. The cell insulation layer 132 may include any of various insulating materials. For example, the cell insulation layer 132 may include silicon oxide, silicon nitride, silicon oxynitride, a low dielectric constant material having a lower dielectric constant than silicon oxide, or a combination thereof.

In an embodiment, the channel structure CH is present. The channel structure CH may extend in a direction crossing the second substrate 110 (e.g., a vertical direction perpendicular to the second substrate 110 or the Z-axis direction in the drawings) to pass through the gate stacking structure 120.

In an embodiment, the channel structure CH includes a channel layer 140, and a gate dielectric layer 150 disposed on the channel layer 140 between the gate line 130 and the channel layer 140. As shown in FIG. 2, the channel structure CH may further include a core insulation layer 142 disposed inside of the channel layer 140. In some embodiments, the core insulation layer 142 is omitted. The channel structure CH may further include a channel pad 144 disposed on the channel layer 140 and/or the gate dielectric layer 150. In an embodiment, the gate dielectric layer 150 between the gate line 130 and the channel layer 140 includes a tunneling layer 152, a charge storage layer 154, and a blocking layer 156 sequentially disposed on the channel layer 140.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape or a zigzag shape, in a plan view. The channel structure CH may have a pillar shape. For example, the channel structure CH may have an inclined side surface such that a width of the channel structure CH decreases toward the second substrate 110 due to an aspect ratio. However, the embodiments are not limited thereto, and an arrangement, a structure, a shape, or so on of the channel structure CH may be variously modified.

The channel layer 140 may include a semiconductor material (e.g., polycrystalline silicon). The core insulation layer 142 may include or be any of various insulating materials. For example, the core insulation layer 142 may include silicon oxide, silicon nitride, silicon oxynitride, or a combination thereof.

In an embodiment, the tunneling layer 152 includes an insulating material that is capable of tunneling a charge (e.g., silicon oxide or silicon oxynitride). The charge storage layer 154 may be used as a data storage region, and the charge storage layer 154 may include or be polycrystalline silicon or silicon nitride. In an embodiment, the blocking layer 156 includes an insulating material that is capable of preventing an undesirable charge from flowing into the gate line 130. The blocking layer 156 may include, for example, silicon oxide, silicon nitride, silicon oxynitride, a high dielectric constant material having a higher dielectric constant than silicon oxide, or a combination thereof. In an embodiment, the blocking layer 156 includes a first blocking layer 156a including a portion horizontally extending on the gate line 130, and a second blocking layer 156b vertically extending between the first blocking layer 156a and the charge storage layer 154. In an embodiment, the first blocking layer 156a includes a first horizontal portion, a second horizontal portion and vertical portion connecting the horizontal portions.

However, a material, a stacking structure, or so on of the channel layer 140, the core insulation layer 142, and the gate dielectric layer 150 may be variously modified, and the embodiments are not limited thereto.

The channel pad 144 may cover an upper surface of the core insulation layer 142 and be disposed to be electrically connected to the channel layer 140. The channel pad 144 may include a conductive material (e.g., polycrystalline silicon doped with a dopant), but the embodiments are not limited thereto.

In an embodiment, the gate stacking structure 120 includes the plurality of gate stacking structures 120a and 120b sequentially stacked. Then, a number of stacked gate lines 130 may be increased and thus a number of memory cells may be increased with a stable structure. In FIG. 1, it is illustrated as an example that the gate stacking structure 120 includes first and second gate stacking structures 120a and 120b. In some embodiments, the gate stacking structure 120 includes a single gate stacking structure or three or more gate stacking structures.

When the plurality of gate stacking structures 120a and 120b are disposed in the above, the channel structure CH may include a plurality of channel structures CH1 and CH2 that respectively pass through the plurality of gate stacking structures 120a and 120b. The plurality of channel structures CH1 and CH2 may have a shape in which the plurality of channel structures CH1 and CH2 are connected to each other. In a cross-sectional view, each of the plurality of channel structures CH1 and CH2 may have an inclined side surface such that a width of each of the plurality of channel structures CH1 and CH2 decreases toward the second substrate 110 according to an aspect ratio. A bent portion due to a difference in widths of the plurality of channel structures CH1 and CH2 may be provided at a connection portion of the plurality of channel structures CH1 and CH2. In some embodiments, the plurality of channel structures CH1 and CH2 have an inclined side surface that is continuously extended without the bent portion. In FIG. 2, it is illustrated as an example that the gate dielectric layer 150, the channel layer 140, and the core insulation layer 142 of the plurality of channel structures CH1 and CH2 continuously extend to have an integral structure. However, in some embodiments, the gate dielectric layers 150, the channel layers 140, and the core insulation layers 142 of the plurality of channel structures CH1 and CH2 are separately formed and are electrically connected to each other. In some embodiments, a separate channel pad is additionally disposed at the connection portion of the plurality of channel structures CH1 and CH2. As such, the embodiments are not limited to a shape of a plurality of channel structures CH1 and CH2 illustrated here.

In an embodiment, the gate stacking structure 120 is divided into a plurality of portions in a plan view by a separation structure 146 extending in a direction crossing the second substrate 110 (e.g., in a vertical direction or the Z-axis direction in the drawings) to pass through the gate stacking structure 120. An upper separation region 148 may be disposed at a portion adjacent to an upper portion of the gate stacking structure 120. In a plan view, a plurality of separation structures 146 and/or a plurality of upper separation regions 148 may extend in the extension direction D2 of the gate line 130 and be spaced apart from each other at a predetermined interval in the transverse direction D1 of the gate line 130.

The separation structure 146 and/or the upper separation regions 148 may be filled with any of various insulating materials. For example, the separation structure 146 or the upper separation region 148 may include an insulating material such as silicon oxide, silicon nitride, or silicon oxynitride. However, the embodiments are not limited thereto, and a structure, a shape, a material, or so on of the separation structure 146 or the upper separation region 148 may be variously modified.

The connection region 104 and the second wiring portion 180 may be used to connect the gate stacking structure 120 and the channel structure CH in the cell array region 102 to the circuit region 200 or an external circuit. The connection region 104 may be disposed at a periphery of the cell array region 102 and a partial portion of the second wiring portion 180 may be disposed in the connection region 104.

The second wiring portion 180 may include a member electrically connecting the gate line 130, the channel structure CH, the horizontal conductive layers 112 and 114, and/or the second substrate 110 to the circuit region 200 or the external circuit. For example, the second wiring portion 180 may include a bit line 182, a gate contact portion 184, a source contact portion 186, a through plug 188, a contact via 180a, and a connection wiring 190. The contact via 180a may be connected to each of the bit line 182, the gate contact portion 184, the source contact portion 186, and/or the through plug 188. The connection wiring 190 may be electrically connected to the bit line 182, the gate contact portion 184, the source contact portion 186, the through plug 188, and/or the contact via 180a.

The bit line 182 may extend in the transverse direction D1 that is transverse to the extension direction D2 of the gate line 130. The bit line 182 may be electrically connected to the channel structure CH (e.g., the channel pad 144) through the contact via 180a (e.g., a bit line contact via).

In the connection region 104, a plurality of gate contact portions 184 may pass through the cell insulation layer 132 to be electrically connected to a plurality of gate lines 130, respectively, extended to the connection region 104. In the drawing, it is illustrated as an example that the plurality of gate lines 130 have a stair or step shape in one direction or a plurality of directions in the connection region 104, but the embodiments are not limited thereto. In the connection region 104, the source contact portion 186 may pass through the cell insulation layer 132 to be electrically connected to the horizontal conductive layers 112 and 114 and/or to the second substrate 110. The through plug 188 may pass through the gate stacking structure 120 or may be disposed outside of the gate stacking structure 120 to be electrically connected to the first wiring portion 230 of the circuit region 200.

In FIG. 1, it is illustrated as an example that each of the gate contact portions 184, the source contact portion 186, and/or the through plug 188 has an inclined side surface such that a width of each of the gate contact portion 184, the source contact portion 186, and/or the through plug 188 decreases toward the second substrate 110 due to an aspect ratio and a bent portion is disposed at a boundary portion of the plurality of gate stacking structures 120a and 120b in a cross-sectional view. However, the embodiments are not limited thereto. In some embodiments, the gate contact portion 184, the source contact portion 186, and/or the through plug 188 might not include the bent portion at the boundary portion of the plurality of gate stacking structures 120a and 120b.

In FIG. 1, it is illustrated as an example that the connection wiring 190 is a single layer on the same plane as the bit line 182 and a second insulation layer 192 is disposed at a portion other than the second wiring portion 180. However, embodiments are not limited thereto. For an electrical connection with the bit line 182, the gate contact portion 184, the source contact portion 186, and/or the through plug 188, the connection wiring 190 may include a plurality of wiring layers and may further include a contact via.

Due to the second wiring portion 180 and the first wiring portion 230, the bit line 182 connected to the channel structure CH, the gate line 130, the horizontal conductive layers 112 and 114, and/or the second substrate 110 may be electrically connected to the circuit element 220 of the circuit region 200.

The circuit region 200 may include the first substrate 210, and a circuit element 220 and the first wiring portion 230 disposed on the first substrate 210.

The first substrate 210 may be a semiconductor substrate including a semiconductor material. For example, the first substrate 210 may be a semiconductor substrate including or formed of a semiconductor material or may be a semiconductor substrate in which a semiconductor layer is disposed on a base substrate. For example, the first substrate 210 may include single-crystalline or polycrystalline silicon, epitaxial silicon, germanium, silicon-germanium, silicon on insulator or germanium on insulator.

The circuit element 220 disposed on the first substrate 210 may include any of various circuit elements that control an operation of the memory cell structure in the cell region 100. For example, the circuit element 220 may constitute the peripheral circuit structure such as a decoder circuit 1110 (refer to FIG. 17), a page buffer 1120 (refer to FIG. 17) or a logic circuit 1130 (refer to FIG. 17).

The circuit element 220 may include, for example, a plurality of transistors 222, but the embodiments are not limited thereto. In an embodiment, the plurality of transistors 222 include a first transistor 222a and a second transistor 222b. This will be described later in more detail. The circuit element 220 may include not only an active element such as the transistor 222 but also a passive element such as a capacitor, a resistor or an inductor.

The first wiring portion 230 disposed on the first substrate 210 may be electrically connected to the circuit element 220. In an embodiment, the first wiring portion 230 includes a plurality of wiring layers 236 that are spaced apart from each other while interposing a first insulation layer 232 therebetween and are electrically connected by a contact via 234 to form a desired path. The wiring layers 236 or the contact via 234 may include any of various conductive materials, and the first insulation layer 232 may include any of various insulating materials. For example, among the plurality of wiring layers 236, a wiring layer 236 at an uppermost portion adjacent to the cell region 100 may include or constitute a pad portion to which the gate contact portion 184, the source contact portion 186 or the through plug 188 is connected.

Referring to FIG. 3 together with FIG. 1 and FIG. 2, the circuit region 200 including the plurality of transistors 222 and contacts (e.g., a gate contact 234g and a plurality of contacts 2341) connected to the plurality of transistors 222 will be described in more detail.

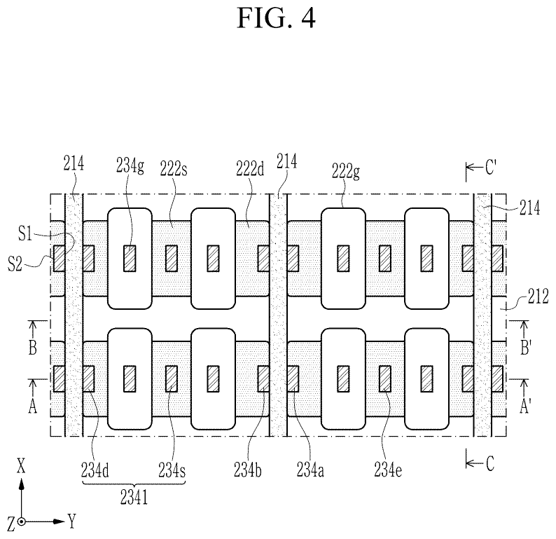

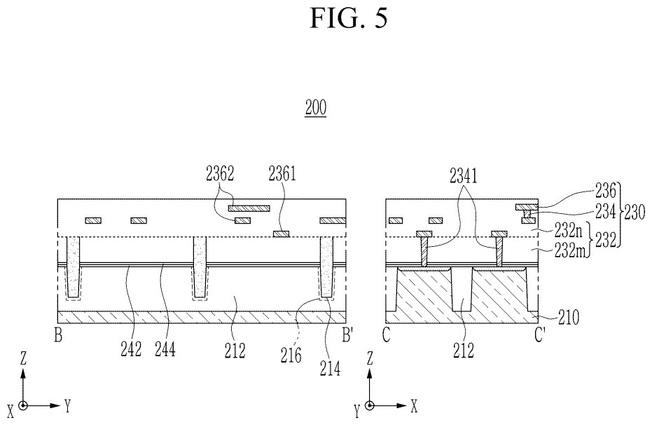

FIG. 3 is a cross-sectional view schematically illustrating the circuit region 200 included in the semiconductor device 10 illustrated in FIG. 1. FIG. 4 is a partial plan view schematically illustrating the circuit region 200 included in the semiconductor device 10 illustrated in FIG. 1. FIG. 5 is a schematic cross-sectional view taken along line B-B′ and line C-C′ of FIG. 4.

FIG. 3 illustrates a cross-sectional view of the circuit region 200 where a gate structure 222g, source and drain regions 222s and 222d are positioned together. In a left portion of FIG. 3, a first transistor region A1 where a first transistor 222a is disposed is illustrated. In a right portion of FIG. 3, a second transistor region A2 where a second transistor 222b is disposed is illustrated. The left portion of FIG. 3 is a cross-sectional view taken along line A-A′ of FIG. 4. FIG. 4 is a plan view of the first transistor region A1 where the first transistor 222a is disposed. For simple illustration and a clear understanding, the gate structure 222g, source and drain regions 222s and 222d, the gate contact 234g connected to the gate structure 222g, and the plurality of contacts 2341 connected to the source and drain regions 222s and 222d are mainly illustrated in FIG. 4.

Referring to FIG. 1 to FIG. 5, in an embodiment, a plurality of transistors 222 are disposed on or at the first substrate 210. In this instance, each of the plurality of transistors 222 may include a gate structure 222g on the first substrate 210, and source and drain regions 222s and 222d. The gate structure 222g may include a gate insulation layer 224, a gate electrode 226, a gate capping layer 228, and a gate spacer 229.

In an embodiment, each transistor 222 has a planar structure. That is, the gate insulation layer 224 may horizontally extend on a surface of the first substrate 210, and the gate electrode 226 may horizontally extend on the gate insulation layer 224. In a plan view, the source and drain regions 222s and 222d may be disposed at both sides of the gate structure 222g. The transistor 222 having the planar type may be stably applied to a memory device (e.g., a flash memory device) including the plurality of transistors 222 having various operating voltage or performing various functions.

The gate capping layer 228 may be disposed on the gate electrode 226, and the gate spacer 229 may be disposed on a side surface of the gate electrode 226. The gate capping layer 228 may serve as a mask layer when the gate insulation layer 224 and the gate electrode 226 are formed. The gate spacer 229 may insulate the gate structure 222g from the source and drain regions 222s and 222d. For example, the gate spacer 229 may extend in a first direction (an X-direction in the drawing) at both sides in a second direction (a Y-direction in the drawing) that is transverse to the first direction. The first direction may be parallel to an extension direction of the gate structure 222g, and the second direction may be a direction where the gate structure 222g, and the source and drain regions 222s and 222d are positioned together.

In the drawings, it is illustrated as an example that the gate spacer 229 is disposed on a side surface of the gate capping layer 228. In some embodiments, the gate capping layer 228 may be disposed on the gate spacer 229.

The gate insulation layer 224 may include at least one of oxide, nitride, oxynitride, a high dielectric constant material having a higher dielectric constant than silicon oxide, or a low dielectric constant material having a lower dielectric constant than silicon oxide. For example, the first gate insulation layer 224 may include at least one of silicon oxide, silicon nitride, silicon oxynitride, hafnium oxide, aluminum oxide, or tantalum oxide. The gate insulation layer 224 may include a single insulation layer or may include a plurality of insulation layers.

The gate electrode 226 may include or be a conductive material. For example, the gate electrode 226 may include at least one of metal, a metal alloy, metal nitride, metal silicide, or a doped semiconductor material. Here, the metal or the metal alloy included in the gate electrode 266 may include at least one of titanium, tungsten, molybdenum, aluminum, copper, cobalt, tantalum, or ruthenium. The metal nitride when included in the gate electrode 266 may include at least one of titanium nitride, tungsten nitride, molybdenum nitride, or tantalum nitride. The gate electrode 266 may further include metal oxide or metal oxynitride in which the above material is oxidized. The doped semiconductor material may include a semiconductor material (e.g., a polycrystalline semiconductor material) doped with an n-type dopant or a p-type dopant.

While an example is discussed where the gate electrode 226 includes a first electrode layer 226a including a semiconductor layer and a second electrode layer 226b including a metal-containing layer including a metal, embodiments are not limited thereto. For example, a material, a stacking structure, or so on of the gate electrode 226 may be variously modified.

The gate capping layer 228 may include any of various insulating materials such as oxide, nitride or oxynitride. For example, the gate capping layer 228 may include or be formed of at least one of silicon oxide, silicon nitride, or silicon oxynitride.

The gate spacer 229 may include any of various insulating materials such as oxide, nitride, oxynitride or a low dielectric constant material. For example, the gate spacer 229 may include or be formed of a material that includes at least one of silicon oxide, silicon nitride, or silicon nitride, or a material where carbon is additionally included in the above material. The gate spacer 229 may include a single insulation layer or may include a plurality of insulation layers.

The source and drain regions 222s and 222d may include or be formed of a doping region formed by doping a partial portion of the first substrate 210. For example, the source and drain regions 222s and 222d may be portions formed by doping an n-type dopant or a p-type dopant into the partial portion of the first substrate 210. In this instance, a conductive type of a dopant included in the source and drain regions 222s and 222d may be opposite to a conductive type of a dopant included in the first substrate 210.

However, the embodiments are not limited thereto. In some embodiments, the gate insulation layer 224, the gate electrode 226, the gate capping layer 228, the gate spacer 229, and/or the source and drain regions 222s and 222d may have any of various materials, structures, or so on.

In an embodiment, the plurality of transistors 222 include a first transistor 222a and a second transistor 222b having different operating voltages. For example, the first transistor 222a may be a low voltage (LV) transistor having a relatively low operating voltage, and the second transistor 222b may be a high voltage (HV) transistor having an operating voltage higher than or greater than the operating voltage of the first transistor 222a.

For example, the operating voltage of the first transistor 222a may range from about 0.1V to about 10V, and the operating voltage of the second transistor 222b may greater than the operating voltage of the first transistor 222a and may range from about 10V to about 100V. However, the embodiments are not limited to these ranges of operating voltages.

The first transistor 222a, which is the low voltage transistor, may have a high-speed operation property and excellent reliability, and thus, may be applied in an embodiment that requires high-speed operation. The second transistor 222b, which is the high voltage transistor, may be applied in an embodiment that needs to generate or transmit a high voltage. For example, at least a part of transistors included in the page buffer 1120 (refer to FIG. 17) may be the first transistor 222a, and at least a part of transistors included in the decoder circuit 1110 (refer to FIG. 17) may be the second transistor 222b.

In an embodiment, a thickness of the gate insulation layer 224 in the first transistor 222a is less than a thickness of the gate insulation layer 224 in the second transistor 222b. A channel length (a distance between the source region 222s and the drain region 222d) in the first transistor 222a may be less than a channel length (a distance between the source region 222s and the drain region 222d) in the second transistor 222b. A width of the gate electrode 226 of the first transistor 222a in the second direction (the Y-direction in the drawing) may be less than a width of the gate electrode 226 of the second transistor 222b in the second direction. Thereby, the second transistor 222b, which is the high voltage transistor, may stably withstand a high potential difference between the gate electrode 226 and the source and drain regions 222s and 222d.

For example, a lower surface of the gate insulation layer 224 included in the first transistor 222a may be higher than a lower surface of the gate insulation layer 224 included in the second transistor 222b, and an upper surface of the gate insulation layer 224 included in the first transistor 222b and an upper surface of the gate insulation layer 224 included in the second transistor 222b may be on the same plane. In some embodiments, a lower surface of the gate insulation layer 224 included in the first transistor 222a and a lower surface of the gate insulation layer 224 included in the second transistor 222b are on the same plane, and an upper surface of the gate insulation layer 224 included in the second transistor 222b is higher than an upper surface of the gate insulation layer 224 included in the first transistor 222b.

In FIG, 1, it is illustrated as an example that the plurality of first transistors 222a or the first transistor region A1 is disposed at a lower portion of the cell array region 102 and the plurality of second transistors 222b or the second transistor region A2 is disposed at a lower portion of the connection region 104. However, the embodiments are not limited thereto. At least one of the first transistor 222a and the second transistor 222b may be disposed at the lower portion of the cell array region 102, or at least one of the first transistor region A1 or the second transistor region A2 may be disposed at the lower portion of the cell array region 102. At least one of the first transistor 222a and the second transistor 222b may be disposed at the lower portion of the connection region 104, or at least one of the first transistor region A1 or the second transistor region A2 may be disposed at the lower portion of the connection region 104. Further, positions of the first transistor 222a and the second transistor 222b may be variously modified.

The capping layer 244 may cover the gate structure 222g on a first surface 2101 (e.g., a front surface or an upper surface) of the first substrate 210. The capping layer 244 may be entirely on the first surface 2101 of the first substrate 210, and an upper surface and a side surface of the gate structure 222g in an area except for the gate contact 234g and the plurality of contacts 2341. The capping layer 244 may be a layer that prevents undesired diffusion of dopants doped in the source and drain regions 222s and 222d. Depending on the embodiment, a buffer layer 242 may be further positioned between the first surface 2101 of the first substrate 210 and the capping layer 244. The buffer layer 242 may be a layer to compensate for a difference in lattice constant between the first substrate 210 and the capping layer 244.

For example, the capping layer 244 may include silicon nitride or silicon oxynitride, and the buffer layer 242 may include silicon oxide. However, the embodiments are not limited thereto. The capping layer 244 or the buffer layer 242 may include any of various materials. In some embodiments, the buffer layer 242 is omitted.

A first interlayer insulation layer 232m may be disposed on the gate structure 222g and the capping layer 244 on the first substrate 210. The first interlayer insulation layer 232m may be entirely on the capping layer 224 on the first surface 2101 of the first substrate 210 and the upper surface and the side surface of the gate structure 222g in an area except for the gate contact 234g and the plurality of contacts 2341. In this instance, the first interlayer insulation layer 232m may include an upper portion 232u disposed on the gate structure 222g, and a side portion 2321 disposed on the source and drain regions 222s and 222d disposed at a side of the first surface 2101 of the first substrate 210. The side portion 2321 may be disposed on the side surface of the gate structure 222g (more particularly, a side surface of the capping layer 244 on the side surface of the gate structure 222g) in an area where the gate structure 222g is not positioned. The side portion 2321 may fill a space between neighboring gate structures 222g adjacent to each other (more particularly, a space between the capping layers 244 on side surfaces of the neighboring gate structures 222g), or fill a space between the gate structure 222g and the separation insulator 214 adjacent to each other (more particularly, a space between the capping layer 244 on the side surface of the gate structure 222g and the separation insulator 214 adjacent to each other).

The gate contact 234g and the plurality of contacts 2341 may pass through or penetrate the first interlayer insulation layer 232m, the capping layer 244, and/or the buffer layer 242. For example, the gate contact 234g may pass through the first interlayer insulation layer 232m, the capping layer 244, and the gate capping layer 228 to be electrically connected to the gate electrode 226. The plurality of contacts 2341 may include a source contact 234s connected to the source region 222s and a drain contact 234d connected to the drain region 222d. The source contact 234s and the drain contact 234d may pass through the first interlayer insulation layer 232m, the capping layer 244, and the buffer layer 242. A first wiring layer 2361 connected to the gate contact 234g and the plurality of contacts 2341 that are connected to the second transistor 222b may be disposed on the first interlayer insulation layer 232m. One or a plurality of second interlayer insulation layers 232n and one or a plurality of second wiring layers 2362 may be further disposed on the first wiring layer 2361.

In an embodiment, a device separator 212 and a separation insulator 214 are disposed at a side of the first surface 2101 of the first substrate 210. The device separator 212 and the separation insulator 214 may be disposed at a boundary or boundaries of the plurality of transistors 222 to separate active regions of the plurality of transistors 222 at the side of the first surface 2101 of the first substrate 210.

More particularly, the device separator 212 may be disposed at a partial portion of the boundary of the first transistor 222a, and the separation insulator 214 may be disposed at another partial portion of the boundary of the first transistor 222a.

For example, in the first transistor region A1, the device separator 212 may be disposed at a boundary or boundaries at one side or both sides of the first transistor 222a in the first direction (the X-direction in the drawing) and may extend in the second direction (the Y-direction in the drawing). Thereby, the device separator 212 may separate the active regions of the plurality of transistors 222 adjacent to each other in the first direction at the side of the first surface 2101 of the first substrate 210. In the first transistor region A1, the separation insulator 214 may be disposed at a boundary or boundaries at one side or both sides of the first transistor 222a in the second direction (the Y-direction in the drawing) and may extend in the first direction (the X-direction in the drawing). For example, the separation insulator 214 may separate the source and drain regions 222s and 222d of the plurality of transistors 222 at the side of the first surface 2101 of the first substrate 210. For example, the separation insulator 214 may be disposed to keep the source and drain regions 222s and 222d spaced apart from one another by a certain distance.

In the first direction (the X-direction in the drawing), that is, the extension direction of the gate structure 222g, an interval between the first transistors 222a may be relatively large to secure an insulation property. For example, a first interval of the first transistors 222a in the first direction (the X-direction in the drawing) may be greater than a second interval of the first transistors 222a in the second direction (the Y-direction in the drawing). Accordingly, the separation insulator 214 may be formed at the boundary of the first transistor 222a having a relatively small interval to reduce an interval between the plurality of contacts 2341. However, the embodiments are not limited thereto. For example, a position of the separation insulator 214 may be variously modified.

In an embodiment, the device separator 212 is disposed at a boundary of the second transistor 222b, and the separation insulator 214 might not be at the boundary of the second transistor 222b. More particularly, in the second transistor region A2, the device separator 212 may include a portion extending in the second direction (the Y-direction in the drawing) at a boundary or boundaries at one side or both sides of the second transistor 222b in the first direction (the X-direction in the drawing), and another portion extending in the first direction and at a boundary or boundaries at one side or both sides of the second transistor 222b in the second direction.

Since the second transistor 222b is the high voltage transistor having the relatively large operating voltage, an interval between the second transistors 222b in the second direction (the Y-direction in the drawing) may be greater than the second interval between the first transistors 222a in the second direction. Accordingly, the separation insulator 214 for reducing an interval between the plurality of contacts 2341 might not be formed at the boundary of the second transistor 222b. However, the embodiments are not limited thereto. For example, the separation insulator 214 may be disposed at least at a partial portion of the boundary of the second transistor 222.

In an embodiment, a width of the device separator 212 extending in the second direction (the Y-direction in the drawing) at the boundary of the first transistors 222a is less than a width of the device separator 212 extending in the second direction at the boundary of the second transistors 222b. Here, the width of the device separator 212 may refer to a width in a direction that is transverse to an extension direction of the device separator 212, and for example, a maximum width of the device separator 212. This is because the operating voltage of the second transistor 222b is greater than the operating voltage of the first transistor 222a. However, the embodiments are not limited thereto. For example, the width of the device separator 212 extending in the second direction at the boundary of the first transistors 222a may be the same as or greater than the width of the device separator 212 extending in the second direction at the boundary of the second transistors 222b.

In an embodiment, a width of the separation insulator 214 extending in the first direction (the X-direction in the drawing) at the boundary of the first transistors 222a is less than a width of the device separator 212 extending in the first direction at the boundary of the second transistors 222b. Here, the width of the separation insulator 214 may refer to a width in a direction that is transverse to an extension direction of the separation insulator 214, and for example, a maximum width of the separation insulator 214. This is because the operating voltage of the second transistor 222b is greater than the operating voltage of the first transistor 222a. However, the embodiments are not limited thereto. For example, the width of the separation insulator 214 extending in the first direction at the boundary of the first transistors 222a may be the same as or greater than the width of the device separator 212 extending in the first direction at the boundary of the second transistors 222b.

In an embodiment, the device separator 212 and the separation insulator 214 may be formed by different processes and may be at different positions, have different structures, or include or be formed of different materials.

For example, the device separator 212 may be an insulator having a shallow trench isolation (STI) structure for separating the active regions of the first and second transistors 222a and 222b. The device separator 212 may pass through a partial portion of the first substrate 210. For example, the device separator 212 may extend from an upper surface of the first substrate 210 to an interior of the first substrate 210. Accordingly, a surface (e.g., an upper surface) of the device separator 212 adjacent to a surface of the first interlayer insulation layer 232m opposite to the first substrate 210 may be on the same plane as or adjacent to the first surface 2101 of the first substrate 210. Here, the phrase that the two surfaces are on the same plane may include a case where the two surfaces are completely on the same plane and a case where the two surfaces are formed by the same process (e.g., a forming process, an etching process, a polishing process, or so on) and thus are close or adjacent to each other. The other surface (e.g., a lower surface) of the device separator 212 inside the first substrate 210 may be between the first surface 2101 of the first substrate 210 and a second surface 2102 (e.g., a lower surface) of the first substrate 210.

In a cross-sectional view (a YZ plane in the drawing) perpendicular to the first direction (the X-direction in the drawing), a side surface of the device separator 212 may include or be formed of an inclined surface so that a width of the device separator 212 gradually decreases from the first surface 2101 of the first substrate 210 to the second surface 2102 of the first substrate 210. The side surface of the device separator 212 may have the inclined surface by forming a trench for the device separator 212 through an etching process performed at a side of the first surface 2101 of the first substrate 210. However, the embodiments are not limited thereto. In some embodiments, the side surface of the device separator 212 may include or be formed of a vertical surface perpendicular to the first substrate 210.

The separation insulator 214 may be an insulator having a trench isolation structure for separating the active regions of the first transistors 222a. The separation insulator 214 may be a self-align insulator for a self-alignment of the plurality of contacts 2341 connected to the source and drain regions 222s and 222d. This will be described in more detail.

The separation insulator 214 may pass through the first interlayer insulation layer 232m, and a partial portion of the first substrate 210. More particularly, the separation insulator 214 may pass through the first interlayer insulation layer 232m, the capping layer 244, and the buffer layer 242 and extend to an inside of the first substrate 210. That is, the separation insulator 214 may include a first portion 214a and a second portion 214b. The first portion 214a may pass through the first interlayer insulation layer 232m, the capping layer 244, and the buffer layer 242. The second portion 214b may be disposed inside the first substrate 210.

For example, one surface (e.g., an upper surface) of the separation insulator 214 adjacent to the surface of the first interlayer insulation layer 232m opposite to the first substrate 210 may be disposed on the same plane as or adjacent to the surface of the first interlayer insulation layer 232m (that is, an interface between the first interlayer insulation layer 232m and the first wiring layer 2361). The other surface (e.g., a lower surface) of the separation insulator 214 in the first substrate 210 may be disposed between the first surface 2101 of the first substrate 210 and the second surface 2102 of the first substrate 210.

As such, one surface (e.g., an upper surface) of the separation insulator 214 and one surface (e.g., an upper surface) of the separation insulator 214, which are adjacent to the surface of the first interlayer insulation layer 232m opposite to the first substrate 210, may be disposed at different heights or levels.

In an embodiment, the other surface (e.g., a lower surface) of the device separator 212 and the other surface (e.g., a lower surface) of the separation insulator 214, which are inside the first substrate 210, may be disposed at different heights or levels. In FIG. 5, it is illustrated as an example that the other surface of the separation insulator 214 is higher than the other surface of the device separator 212. This may prevent a height of the separation insulator 214 from excessively increasing, but the embodiments are not limited thereto. In some embodiments, the other surface of the separation insulator 214 is on the same plane or level as the other surface of the device separator 212 or may be lower than the other surface of the device separator 212.

In a cross-sectional view (a YZ plane in the drawing) perpendicular to the first direction (the X-direction in the drawing), a recess portion 214r may be disposed at a side surface of the first portion 214a of the separation insulator 214. The recess portion 214r may be disposed at a side of the one surface (e.g., the upper surface) of the separation insulator 214 adjacent to the surface of the first interlayer insulation layer 232m opposite to the first substrate 210. The recess portion 214r may be disposed at both sides of the separation insulator 214 in the second direction (the Y-direction in the drawing) and may have a concave round surface, and may longitudinally extend in the first direction (the X-direction in the drawing) that is the extension direction of the separation insulator 214. In a cross-sectional view (a YZ plane in the drawing) perpendicular to the first direction (the X-direction in the drawing), a side surface of another portion of the separation insulator 214 may have an inclined surface so that a width of the separation insulator 214 gradually decreases toward the second surface 2102 of the first substrate 210.

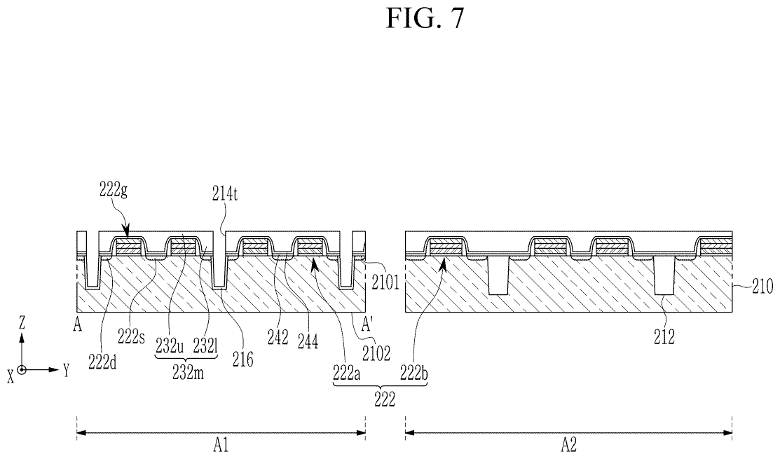

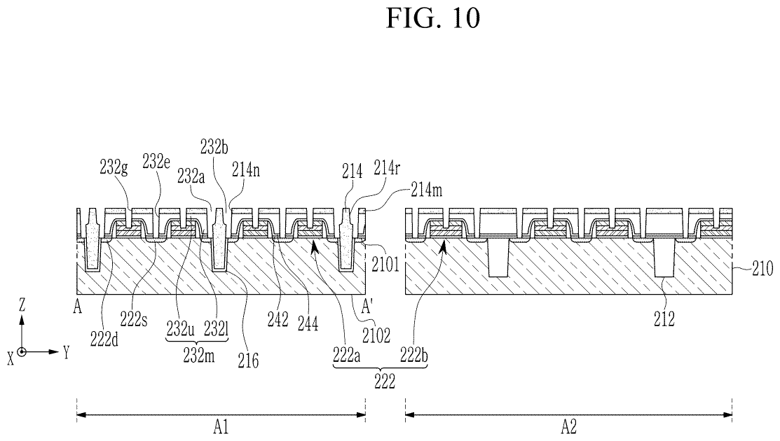

The recess portion 214r of the separation insulator 214 may be formed in an etching process for forming third through portions 232a and 232b (refer to FIG. 10) for the plurality of contacts 2341 (more particularly, a first adjacent contact 234a and a second adjacent contact 234b) disposed at the both sides of the separation insulator 214. A separation trench 214t (refer to FIG. 7) for forming the separation insulator 214 may be formed by an etching process performed at a side of the one surface (e.g., the upper surface) of the first interlayer insulation layer 232m opposite to the first substrate 210. Thereby, the side surface of another portion of the separation insulator 214 may have the inclined surface. However, the embodiments are not limited thereto. In some embodiments, the side surface of another portion of the separation insulator 214 may have a vertical surface perpendicular to the first substrate 210.

In an embodiment, a separating buffer layer 216 having a material different from a material of the separation insulator 214 is disposed between the first substrate 210 and the separation insulator 214 (more particularly, between the first substrate 210 and the second portion 214b of the separation insulator 214). The separating buffer layer 216 may be a layer used to compensate for differences in lattice constants of the first substrate 210 and the separation insulator 214. However, the embodiments are not limited thereto. In an embodiment, the separating buffer layer 216 is omitted.

In an embodiment, the separation insulator 214 includes or is formed of a material different from a material of the device separator 212. This is because the separation insulator 214 may be formed by a process different from a process of forming the device separator 212 and may perform a function different from a role of the device separator 212. The separation insulator 214 may include or be formed of a material different from a material of the first insulation layer 232 (e.g., the first interlayer insulation layer 232m). For example, the separation insulator 214 and the first interlayer insulation layer 232m may include materials having different etch selectivity. Thereby, in a process of forming through portions 232g, 232e, 232a, and 232b (refer to FIG. 10) for forming the gate contact 234g and the plurality of contacts 2341 by etching of a partial portion of the first interlayer insulation layer 232m, the separation insulator 214 may be prevented from being completely removed.

For example, the first insulation layer 232 (e.g., the first interlayer insulation layer 232m) or the device separator 212 may include or be formed of at least one of silicon oxide, silicon nitride, silicon oxynitride, or a low dielectric constant material, and the separation insulator 214 may include or be formed of a material different from the first interlayer insulation layer 232m and at least one of silicon nitride, silicon oxynitride, silicon oxide, or silicon carbide. Here, the low dielectric constant material may be a material having a dielectric constant lower than a dielectric constant of silicon oxide.

For example, the first insulation layer 232 (e.g., the first interlayer insulation layer 232m) or the device separator 212 may include or be formed of silicon oxide, and the separation insulator 214 may include or be formed of silicon nitride. The separating buffer layer 216 may include or be formed of silicon oxide. However, the embodiments are not limited thereto. In some embodiments, the first insulation layer 232, the device separator 212, the separation insulator 214, or the separating buffer layer 216 may include or be formed of any of various materials.

In an embodiment, as shown in FIG. 4, the plurality of contacts 2341 include adjacent contacts 234a and 234b adjacent to (e.g., in contact with) the separation insulator 214. The adjacent contacts 234a or 234b may be self-align contacts formed to be in contact with the separation insulator 214 and thus is self-aligned by the separation insulator 214.

In this instance, the adjacent contacts 234a or 234b may include a contact surface S1 that is in contact with the separation insulator 214, and a cover surface S2 that is spaced apart from the separation insulator 214 and is surrounded by the first interlayer insulation layer 232m. That is, the adjacent contacts 234a or 234b may be spaced apart from the gate structure 222g while interposing a partial portion of the first interlayer insulation layer 232m (more particularly, the side portion 2321 of the first interlayer insulation layer 232m) covering the upper portion of the gate structure 222g and/or the capping layer 244. More particularly, in a cross-sectional view (a YZ plane in the drawing) perpendicular to the first direction (the X-direction in the drawing), the side portion 2321 of the first interlayer insulation layer 232m may be disposed between the cover surface S2 of the adjacent contact 234a or 234b and the side surface of the gate structure 222g (more particularly, the side surface of the capping layer 244 on the side surface of the gate structure 222g).

When the side portion 2321 is disposed between the gate structure 222g and the adjacent contact 234a or 234b, the adjacent contacts 234a or 234b may be prevented from having unwanted effects on the gate structure 222g in a process of forming the adjacent contact 234a or 234b. For example, in a process forming the third through portions 232a and 232b (refer to FIG. 10) for forming the adjacent contacts 234a and 234b, damage or collapse of the gate structure 222g may be prevented. A height or a thickness of the gate structure 222g may be independent of the adjacent contact 234a or 234b. For example, the height or the thickness of the gate structure 222g may be less than a height of the adjacent contact 234a or 234b.

In the first transistor 222a having the planar structure, a distance between the adjacent contacts 234a or 234b and the gate structure 222g may be sufficiently secured, thereby enhancing stability. In an embodiment including the plurality of transistors 222 driven by different operating voltages, a distance between the adjacent contact 234a or 234b and the gate structure 222g may be freely varied by using the side portion 2321.

In an embodiment, the separation insulator 214 may have a shape extending in the first direction (the X-direction in the drawing). The adjacent contacts 234a and 234b may include a first adjacent contact 234a and a second adjacent contact 234b. The first adjacent contact 234a may be disposed at a first side (e.g., a right side of FIG. 4) of the separation insulator 214 in the second direction (the Y-direction in the drawing). The second adjacent contact 234b may be disposed at a second side (e.g., a left side of FIG. 4) of the separation insulator 214 opposite to the first side of the separation insulator 214 in the second direction.

The third through portions 232a and 232b (refer to FIG. 10) for forming the first adjacent contact 234a and the second adjacent contact 234b interposing one separation insulator 214 may be formed together by using an opening 214n (more particularly, a third opening) exposing the one separation insulator 214 and portions including both sides of the one separation insulator 214. The first adjacent contact 234a and the second adjacent contact 234b interposing one separation insulator 214 may be disposed at the same position in the first direction (the X-direction in the drawing). In this instance, the first adjacent contact 234a and the second adjacent contact 234b interposing one separation insulator 214 may be self-aligned together by the one separation insulator 214.

In an embodiment, the plurality of contacts 2341 further include a separated contact 234e that is spaced apart from the separation insulator 214. An entire portion of a side surface of the separated contact 234e may be formed of a cover surface surrounded by the first interlayer insulation layer 232m. That is, the separated contact 234e may be spaced apart from the gate structure 222g while interposing a partial portion of the first interlayer insulation layer 232m (more particularly, the side portion 2321 of the first interlayer insulation layer 232m) covering the upper portion of the gate structure 222g and/or the capping layer 244. For example, part of the first interlayer insulation layer 232m may be interposed between the separated contact 234e and the gate structure 222g. More particularly, in a cross-sectional view (a YZ plane in the drawing) perpendicular to the first direction (the X-direction in the drawing), the side portion 2321 of the first interlayer insulation layer 232m may be disposed between the cover surface of the separated contact 234e and the side surface of the gate structure 222g (more particularly, the side surface of the capping layer 244 on the side surface of the gate structure 222g).

For example, the first adjacent contact 234a, the separated contact 234e, and the second adjacent contact 234b between two adjacent separation insulators 214 may be a drain contact 234d, a source contact 234s, another drain contact 234d, respectively. That is, the source region 222s or the source contact 234s may be shared in two adjacent first transistors 222a. However, the embodiments are not limited thereto. In some embodiments, the first adjacent contact 234a, the separated contact 234e, or the second adjacent contact 234b may be one of the source contact 234s and the drain contact 234d. That is, the plurality of contacts 2341 between two adjacent separation insulators 214 may have various arrangements.

In an embodiment, surfaces (e.g., upper surfaces) of the plurality of contacts 2341 (e.g., the adjacent contacts 234a and 234b and the separated contact 234e) may be disposed on the same plane as or be adjacent to one surface (e.g., an upper surface) of the separation insulator 214.

In an embodiment, a height of the separation insulator 214 is greater than a width W of the separation insulator 214. For example, a height H of the second portion 214b of the separation insulator 214 may be greater than the width W of the separation insulator 214. The height H of the second portion 214b may be measured in a thickness direction of the first substrate 210 (the Z-axis direction in the drawing) and, for example, be a maximum height of the second portion 214b. The width W of the separation insulator 214 may be measured in the second direction (the Y-direction in the drawing) that is transverse to the extension direction of the separation insulator 214 and, for example, be a maximum width of the separation insulator 214. In an embodiment, the height H of the second portion 214b of the separation insulator 214 is greater than a thickness T of the gate structure 222g. The thickness T of the gate structure 222g may be measured in the thickness direction of the first substrate 210 (the Z-axis direction in the drawing) and, for example, be a maximum thickness of the gate structure 222g (e.g., (e.g., the gate structure 222g of the first transistor 222a).

Due to the relatively large height of the separation insulator 214, a physical distance of carriers may be increased and thus the active area of the transistor 222 may be stably separated. However, the embodiments are not limited thereto.

According to an embodiment, the plurality of contacts 2341 are formed by a self-alignment through using the separation insulator 214 and thus a margin for forming the plurality of contacts 2341 may be reduced. That is, the adjacent contacts 234a and 234b may be formed in a state that the adjacent contacts 234a and 234b are in contact with the separation insulator 214, and thus, a margin in consideration of a misalignment of the adjacent contacts 234a and 234b and the separation insulator 214 might not be needed. The first adjacent contact 234a and the second adjacent contact 234b may be spaced apart from each other by the separation insulator 214, and thus, a margin in consideration of a misalignment of the first adjacent contact 234a and the second adjacent contact 234b might not be needed. By reducing the margin for forming the plurality of contacts 2341 (e.g., the adjacent contacts 234a and 234b), a distance between the plurality of transistors 222 (e.g., the first transistor 222a) may be reduced. Accordingly, a size of circuit region 200 may be reduced and an integration degree may be increased.

The semiconductor device 10 including the circuit region 200 may be a flash memory device. In the flash memory device including the plurality of transistors 222 where various voltages are applied, an integration degree may be effectively increased. According to the embodiment, in a flash memory device that includes a large number of gate lines 130 and transistors 222 to increase data storage capacity, the integration degree may be greatly increased.

In the embodiment, the separation insulator 214 is disposed at the boundary of the first transistor 222a or the low voltage transistor, but need not be at the boundary of the second transistor 222b or the high voltage transistor. However, the embodiments are not limited thereto. In some embodiments, the separation insulator 214 may be disposed a boundary of the second transistor 222b or the high voltage transistor, and may be or might not be at the boundary of the first transistor 222a or the low voltage transistor. In the embodiment, each of the first transistor 222a and the second transistor 222b has the planar structure. However, the embodiments are not limited thereto. For example, at least one of the first transistor 222a and the second transistor 222b may have a structure (e.g., a vertical structure or a 3-dimensional structure) different from the planar structure. That is, the separation insulator 214 according to the embodiment may be formed to correspond to various transistors 222.

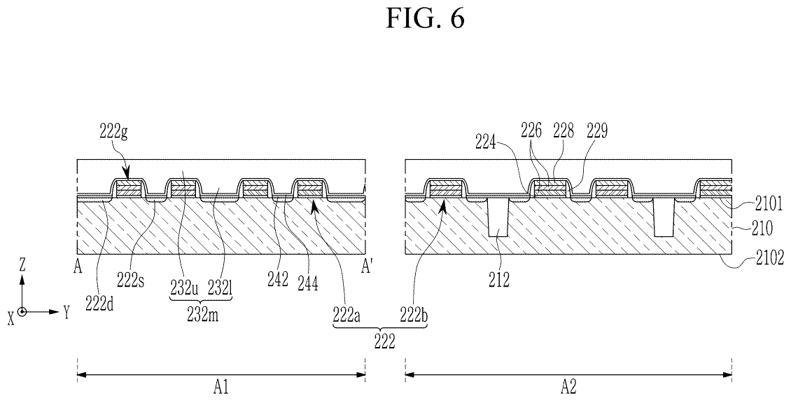

Hereinafter, an example of a manufacturing method of a semiconductor device 10 having the above structure will be described in more detail with reference to FIGS. 6 to 13 together with FIG. 1 to FIG. 5. To the extent that an element is not described in detail below, it may be understood that the element is at least similar to a corresponding element that has been described elsewhere within the present disclosure.

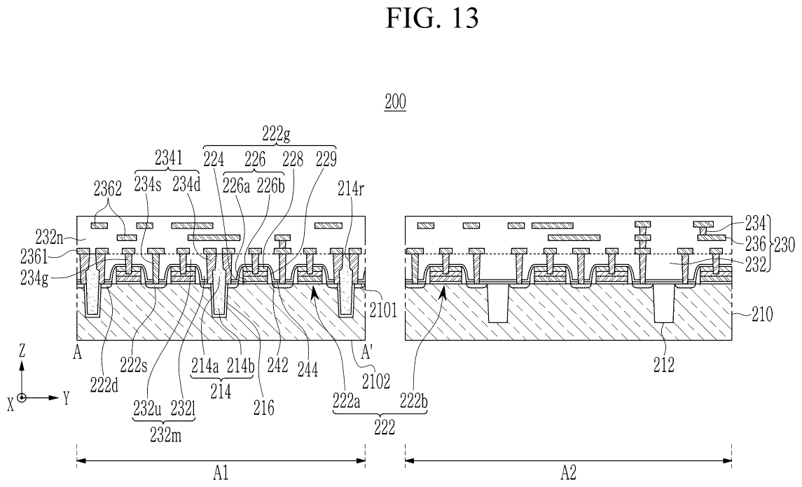

FIG. 6 to FIG. 13 are cross-sectional views illustrating a manufacturing method of a semiconductor device according to an embodiment. In FIG. 6 and FIG. 13, a portion corresponding to FIG. 3 is illustrated. Hereinafter, a manufacturing method of a semiconductor device 10 will be described mainly based on a circuit region 200 (e.g., a transistor 222).

As illustrated in FIG. 6, a plurality of transistors 222 including a first transistor 222a and a second transistor 222b are formed in a first transistor region A1 and a second transistor region A2. That is, the plurality of transistors 222, each including a gate structure 222g, and source and drain regions 222s and 222d, are formed. For example, the transistors 222 may be formed on a first substrate 210. A buffer layer 242, a capping layer 244, and a first interlayer insulation layer 232m may be formed.

A gate insulation layer 224, a gate electrode 226, and a gate capping layer 228 may be formed on a first surface 2101 of the first substrate 210, and then, a patterning of the gate insulation layer 224 and the gate electrode 226 may be performed by using the gate capping layer 228 as a mask. A gate spacer 229 may be formed on a side surface of the gate electrode 226, and then, the source and drain regions 222s and 222d may be formed by using the gate capping layer 228 and the gate spacer 229 as a mask.

The gate insulation layer 224, the gate electrode 226, the gate capping layer 228, or the gate spacer 229 may be formed by any of various methods (such as, deposition or so on). The source and drain regions 222s and 222d may be formed by any of various methods (such as, an ion implantation process or so on). Any of various processes may be applied to a process of forming the plurality of transistors 222.

A device separator 212 and various circuit elements 220 may be further formed together with the plurality of transistors 222 before, between, or after the process forming the plurality of transistors 222. Any of various processes may be applied to the process of forming the device separator 212 and the circuit elements 220. The device separator 212 may be formed by forming a trench through using an etching process performed at a side of the first surface 2101 of a first substrate 210 and filling the trench with an insulating material. For example, a portion of the first substrate 210 may be removed to form the trench.

For example, in the first transistor region A1, the device separator 212 may be formed at a boundary or boundaries at one side or both sides of the first transistor 222a in a first direction (a X-direction in the drawing) and may extend in a second direction (a Y-direction in the drawing). In the second transistor region A2, the device separator 212 may include a portion extending in the second direction (the Y-direction in the drawing) at a boundary or boundaries at one side or both sides of a second transistor 222b in the first direction (the X-direction in the drawing), and another portion extending in the first direction and at a boundary or boundaries at one side or both sides of the second transistor 222b in the second direction.

The buffer layer 242 may be formed on the first surface 2101 of the first substrate 210 at a portion where the gate structure 222g is not positioned. For example, the buffer layer 242 may be formed by any of various processes (such as, deposition or an oxidation process). However, the embodiments are not limited thereto. In some embodiments, the buffer layer 242 may be formed by a heat treatment process performed later, or the buffer layer 242 need not be formed.

The capping layer 244 may be entirely on the first surface 2101 of the first substrate 210 (e.g., on the buffer layer 242) to cover the gate structure 222g. The first interlayer insulation layer 232m may be entirely on the first surface 210 and the gate structure 222g (e.g., on the capping layer 244 on the first substrate 210 and the gate structure 222g). The first interlayer insulation layer 232m may include an upper portion 232u on the gate structure 222g, and a side portion 2321 on the source and drain regions 222s and 222d disposed at a side of the first surface 2101 of the first substrate 210.

The capping layer 244 or the first interlayer insulation layer 232m may be formed by any of various methods (such as deposition).

Subsequently, as illustrated in FIG. 7, a separation trench 214t passing through a partial portion of the first interlayer insulation layer 232m and a partial portion of the first substrate 210 is formed. A separating buffer layer 216 may be formed on a surface of the first substrate 210 exposed by the separation trench 214t.

The separation trench 214t passing through the partial portion of the first interlayer insulation layer 232m and the partial portion of the first substrate 210 may be formed by an etching process performed at a side of a surface (e.g., an upper surface) of the first interlayer insulation layer 232m opposite to the first substrate 210. For example, the separation trench 214t may be formed by an etching process (such as dry etching) through using a mask layer or a photolithography process. For example, the separation trench 214t may be formed by removing portions of the first interlayer insulation layer 232m and the first substrate 210. However, the embodiments are not limited thereto, and the separation trench 214t may be formed by any of various methods.

In an embodiment, in a cross-sectional view (a YZ plane in the drawing) perpendicular to the first direction (the X-direction in the drawing), a side surface of the separation trench 214t may include or be formed of an inclined surface so that a width of the separation trench 214t gradually decreases toward a second surface 2102 (e.g., a lower surface) of the first substrate 210. In some embodiments, the side surface of the device separator 212 may include or be formed of a vertical surface perpendicular to the first substrate 210.

In the first transistor region A1, the separation insulator 214 may be disposed at a boundary or boundaries at one side or both sides of the first transistor 222a in the second direction (the Y-direction in the drawing) and may extend in the first direction (the X-direction in the drawing).

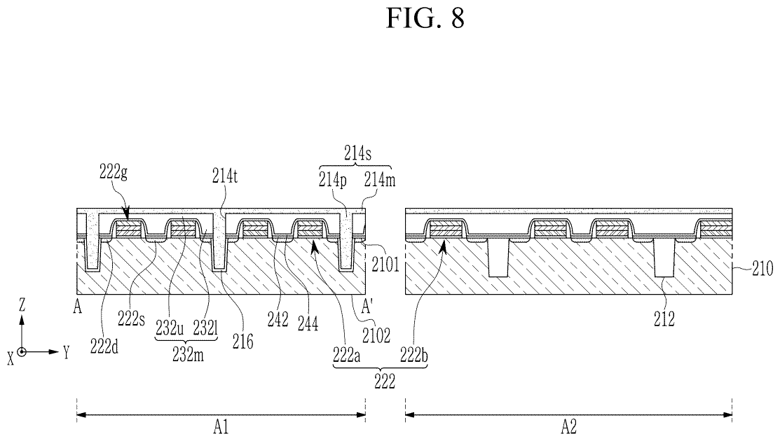

In an embodiment, before a preliminary insulation layer 214s (refer to FIG. 8) is formed, the separating buffer layer 216 may be formed on a surface of the separation trench 214t formed at the first substrate 210. For example, the separating buffer layer 216 may be formed by any of various processes (such as a deposition process or an oxidation process). However, the embodiments are not limited thereto. In some embodiments, the separating buffer layer 216 may be formed by a heat treatment process performed later, or the separating buffer layer 216 need not be formed.

Subsequently, as illustrated in FIG. 8, a preliminary insulation layer 214s that fills the separation trench 214t is formed. The preliminary insulation layer 214s may be formed by forming an insulating material on the first interlayer insulation layer 232m to fill the separation trench 214t.

The preliminary insulation layer 214s may include a preliminary separation insulator 214p filling the separation trench 214t, and a mask portion 214m disposed on the preliminary separation insulator 214p and the first interlayer insulation layer 232m. The mask portion 214m may function as a mask layer for forming through portions 232g, 232e, 232a, 232b (refer to FIG. 10) at the first interlayer insulation layer 232m after the patterning. According to an embodiment, the preliminary insulation layer 214s that fills the separation trench 214t includes the mask portion 214m, and thus, a process of forming an additional mask layer may be omitted.

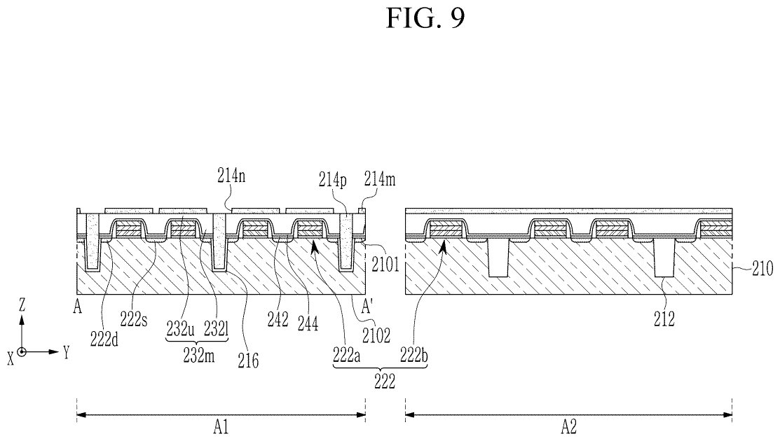

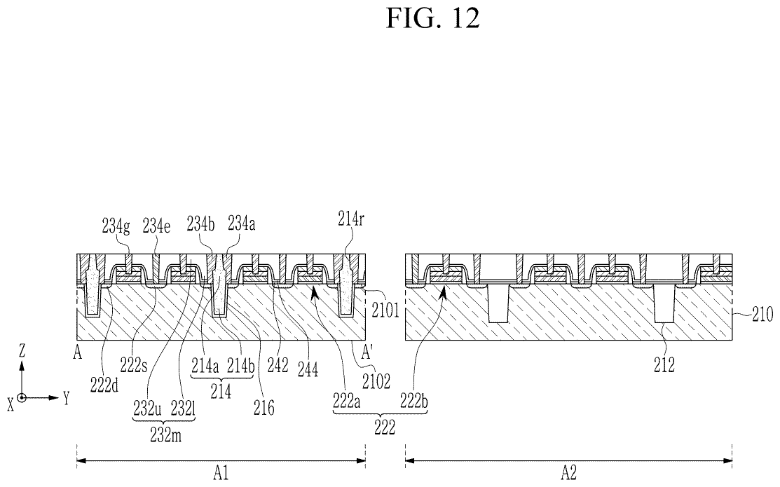

Subsequently, as illustrated in FIG. 9, an opening 214n is formed at the mask portion 214m. The opening 214n may include a plurality of openings corresponding to a plurality of contacts 2341 (refer to FIG. 12) and a gate contact 234g (refer to FIG. 12), respectively. In this instance, the opening 214n may include a first opening, a second opening, and a third opening. The first opening may be at a position corresponding to the gate contact 234g. The second opening may be at a position corresponding to a separated contact 234e (refer to FIG. 12). The third opening may be at a position corresponding to first and second adjacent contacts 234a and 234b (refer to FIG. 12) and the preliminary separation insulator 214p. In a plan view, the third opening may cross the preliminary separation insulator 214p and extend to both sides of the preliminary separation insulator 214p in the second direction (the Y-direction in the drawing), that is transverse to the preliminary separation insulator 214p.

The opening 214n may be formed by an etching process (such as dry etching) through using a mask layer or a photolithography process. In this instance, the opening 214n may be formed at the preliminary insulation layer 214s (refer to FIG. 8) by using an etching material capable of selectively etching the preliminary insulation layer 214s or adjusting an etching thickness.

Subsequently, as illustrated in FIG. 10, through portions 232g, 232e, 232a, and 232b are formed at the first interlayer insulation layer 232m through using the mask portion 214m as a mask.

In this instance, the through portions 232g, 232e, 232a, and 232b may include a first through portion 232g, a second through portion 232e, and third through portions 232a and 232b. The first through portion 232g may be formed at a position corresponding to the first opening or the gate contact 234g. The second through portion 232e may be formatted at a position corresponding to the second opening or the separated contact 234e. The third through portions 232a and 232b may be formed at positions corresponding to partial portions of the third opening or the first and second adjacent contacts 234a and 234b, respectively.

For example, the first through portion 232g may pass through the first interlayer insulation layer 232m, the capping layer 244, and the gate capping layer 228. The second through portion 232e, and the third through portions 232a and 232b may pass through the first interlayer insulation layer 232m, the capping layer 244, and the buffer layer 242.

The through portions 232g, 232e, 232a, and 232b may be formed by a dry etching process capable of selectively etching the first interlayer insulation layer 232m. In a process of forming the through portions 232g, 232e, 232a, and 232b, when the first interlayer insulation layer 232m is selectively etched, a partial portion (e.g., an upper portion at a side surface) of the preliminary separation insulator 214p (refer to FIG. 9) or the separation insulator 214 may be etched together. Thereby, a recess portion 214r may be formed at the partial portion (e.g., the upper portion at the side surface) of the separation insulator 214.

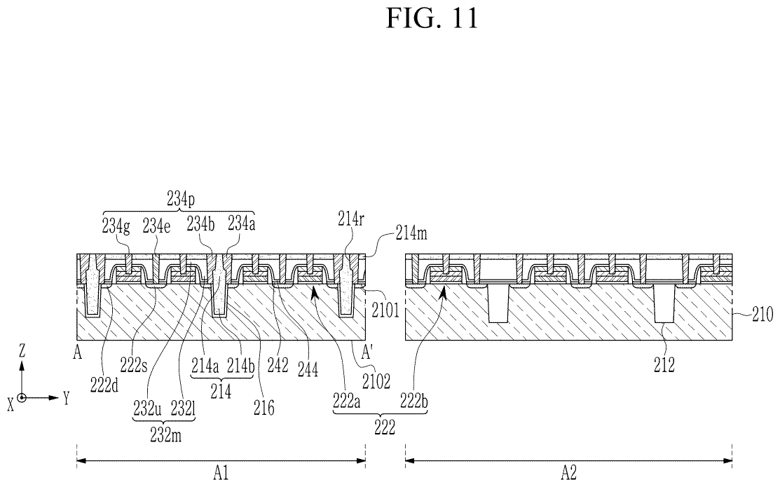

Subsequently, as illustrated in FIG. 11, a preliminary contact layer 234p may be formed by filling a conductive material in the through portions 232g, 232e, 232a, and 232b (refer to FIG. 10). For example, the through portions 232g, 232e, 232a, and 232b may be filled with the conductive material to form the preliminary contact layer 234p.

The preliminary contact layer 234p may be formed by any of various processes (such as a deposition process). The preliminary contact layer 234p (the gate contact 234g and the plurality of contacts 2341) may include or be formed of any of various conductive materials. For example, the preliminary contact layer 234p (the gate contact 234g and the plurality of contacts 2341) may include or be formed of at least one of a metal material (such as, tungsten (W), copper (Cu), aluminum (Al), or so on), polycrystalline silicon, metal nitride (e.g., titanium nitride (TiN), tantalum nitride (TaN), or so on), or combination thereof.

In FIG. 11, it is illustrated as an example that the preliminary contact layer 234p is formed at portions where the through portions 232g, 232e, 232a, and 232b are formed, but the embodiments are not limited thereto. In some embodiments, the preliminary contact layer 234p may further include a portion disposed on an upper surface of the mask portion 214m.

Subsequently, as illustrated in FIG. 12, a plurality of contacts 2341 and a gate contact 234g may be formed by removing the mask portion 214m (refer to FIG. 11). In this instance, the mask portion 214m and a partial portion of the preliminary contact layer 234p (refer to FIG. 11) may be removed so that an upper surface of the first interlayer insulation layer 232m and upper surfaces of the plurality of contacts 2341 and the gate contact 234g are on the same plane. For example, in the process of removing the mask portion 214m and the partial portion of the preliminary contact layer 234p may be performed by a chemical mechanical polishing process.

Subsequently, as illustrated in FIG. 13, one or a plurality of second interlayer insulation layers 232n and one or a plurality of second wiring layers 2362 are further formed on the first wiring layer 2361 to form a first wiring portion 230.

According to an embodiment, the circuit region 200 or the semiconductor device 10 having an increased integration degree may be formed by a manufacturing process described herein.

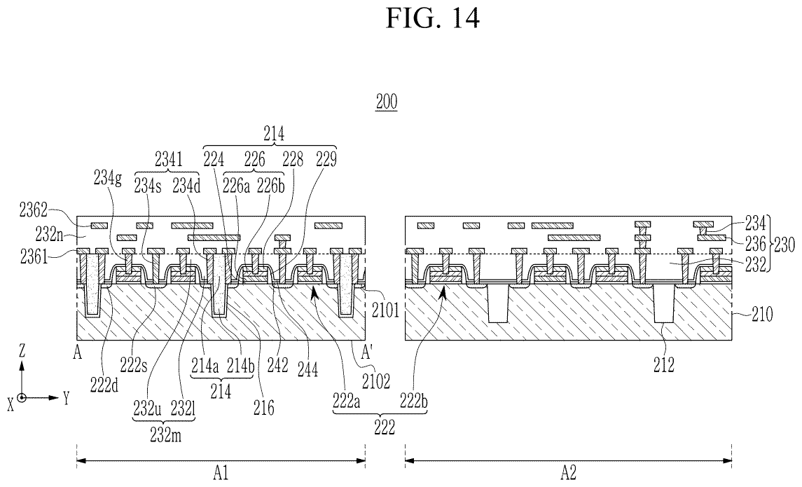

Hereinafter, a semiconductor device and a manufacturing method of the same according to an embodiment will be described in more detail with reference to FIG. 14 to FIG. 16. To the extent that an element is not described in detail below, it may be understood that the element is at least similar to a corresponding element that has been described elsewhere within the present disclosure.

FIG. 14 is a partial cross-sectional view schematically illustrating a circuit region included in a semiconductor device according to an embodiment. In FIG. 14, a portion corresponding to FIG. 3 is illustrated.

Referring to FIG. 14, in a cross-sectional view (a YZ plane in the drawing) perpendicular to a first direction (a X-direction in the drawing), a side surface of an entire portion of a separation insulator 214 may have an inclined surface so that a width of the separation insulator 214 gradually decreases toward the second surface 2102 of a first substrate 210. In some embodiments, the side surface of the entire portion of the separation insulator 214 may have a vertical surface perpendicular to the first substrate 210. As discussed above, in an embodiment, a recess portion 214r (refer to FIG. 3) might not be formed on or at a side surface or an upper portion of the separation insulator 214.

The separation insulator 214 not including the recess portion 214r may be formed by adjusting a process condition so that the recess portion 214r is not formed or by removing the recess portion 214r in the process of removing the mask portion 214m (refer to FIG. 11).

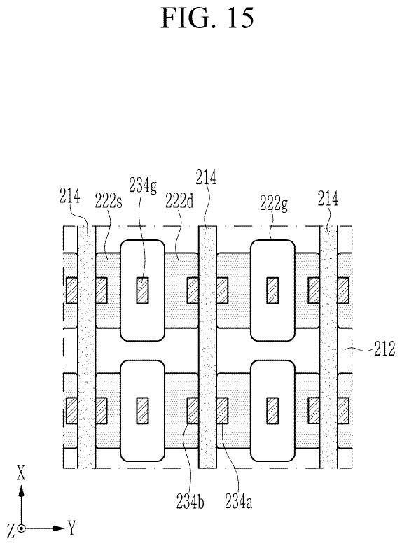

FIG. 15 is a partial cross-sectional view schematically illustrating a circuit region included in a semiconductor device according to an embodiment. In FIG. 15, a portion corresponding to FIG. 4 is illustrated.

Referring to FIG. 15, in an embodiment, a plurality of contacts 2341 may include adjacent contacts 234a and 234b adjacent to a separation insulator 214. A separated contact 234e (refer to FIG. 4) spaced apart from the separation insulator 214 might not be provided. Depending on an electrical connection structure of a plurality of transistors 222, an embodiment referring to FIG. 4 and an embodiment referring to FIG. 15 may be included together. Other various modifications are possible.

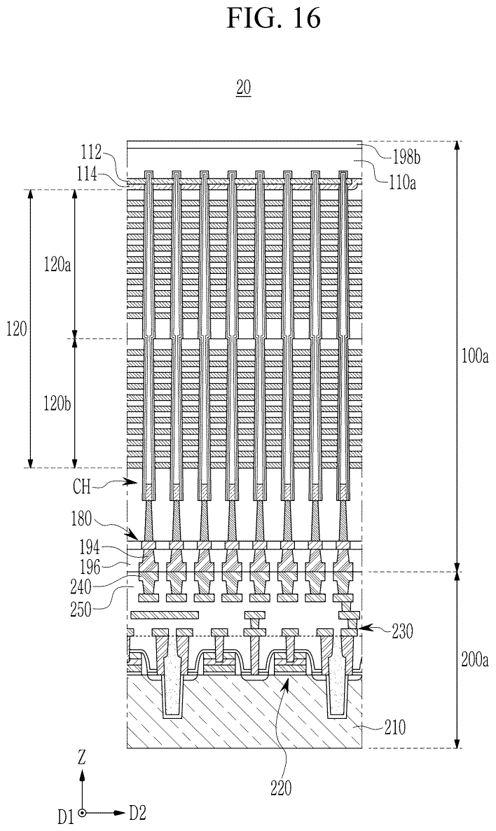

FIG. 16 is a cross-sectional view schematically illustrating a semiconductor device 20 according to an embodiment.

Referring to FIG. 16, a semiconductor device 20 according to an embodiment has a chip-to-chip (C2C) structure bonded by a wafer bonding type. That is, a lower chip including a circuit region 200a including a peripheral circuit structure on a first substrate 210 may be manufactured, an upper chip including a memory cell structure on a second substrate 110a may be manufactured, and then the lower chip and the upper chip may be bonded to each other to manufacture the semiconductor device 20.

The circuit region 200a may include the first substrate 210, a circuit element 220, a first wiring portion 230, and a first bonding structure 240 electrically connected to the first wiring portion 230 at a surface facing the cell region 100a. A region other than the first bonding structure 240 at the surface facing the cell region 100a may be covered by a first bonding insulation layer 250.

The cell region 100a may include the second substrate 110a, a gate stacking structure 120, a channel structure CH, a second wiring portion 180, and a second bonding structure 194 electrically connected the second wiring portion 180 at a surface facing the circuit region 200a. A region other than the second bonding structure 194 may be covered by a second bonding insulation layer 196.

In an embodiment, the second substrate 110a is a semiconductor substrate including a semiconductor material. For example, the second substrate 110a may be a semiconductor substrate including or formed of a semiconductor material, or may be a semiconductor substrate in which a semiconductor layer is formed on a base substrate. For example, the second substrate 110a may include single-crystalline or polycrystalline silicon, germanium, silicon-germanium, silicon-on-insulator or a germanium-on-insulator. In some embodiments, the second substrate 110a may be a supporting member including an insulation layer or an insulating material. This is because a semiconductor substrate provided in the cell region 100a may be removed after the cell region 100a is bonded to the circuit region 200a and the supporting member including the insulation layer or the insulating material may be formed.

In an embodiment, the gate stacking structure 120 may be sequentially stacked on a lower portion of the second substrate 110a in the drawing, and may have a structure in which the gate stacking structure 120 illustrated in FIG. 1 is disposed in a vertically inverted manner. The channel structure CH passing through the gate stacking structure 120 may have a structure in which the channel structure CH illustrated in FIG. 2 is disposed in a vertically inverted manner. Accordingly, in a cross-sectional view, the channel structure CH may have an inclined side surface such that a width of the channel structure CH decreases from the circuit region 200a toward the second substrate 110a. A channel pad and the second wiring portion 180 at an upper portion of the gate stacking structure 120 may be adjacent to the circuit region 200a.

For example, the first bonding structure 240 and/or the second bonding structure 194 may include aluminum, copper, tungsten, or an alloy including the same. For example, the first and second bonding structures 240 and 194 may include copper so that the cell region 100a and the circuit region 200a may be bonded (e.g., directly bonded) to each other by copper-to-copper bonding.

In FIG. 16, it is illustrated as an example that the gate stacking structure 120 includes a plurality of gate stacking structures 120a and 120b. In some embodiments, the gate stacking structure 120 may include a single gate stacking structure or three or more gate stacking structures. Unless otherwise described, the description of the gate stacking structure 120 and the channel structure CH with reference to FIG. 1 to FIG. 5 may be applied as it is. In FIG. 16, it is illustrated as an example that an electrical connection structure of the channel structure CH with horizontal conductive layers 112 and 114 and/or the second substrate 110a is the same as an electrical connection structure of the channel structure CH with the horizontal conductive layers 112 and 114 and/or the second substrate 110 in FIG. 1. However, the embodiments are not limited thereto, and the electrical connection structure of the channel structure CH with the horizontal conductive layers 112 and 114 and/or the second substrate 110a may be variously modified.

The semiconductor device 20 according to an embodiment may include an input/output pad, and a through plug or an input/output connection wiring electrically connected to the input/output pad. The input/output connection wiring may be electrically connected to a part of the second bonding structure 194. For example, the input/output pad may be on an insulation layer 198b covering an outer surface of the second substrate 110a. In some embodiments, an additional input/output pad electrically connected to the circuit region 200a may be provided.

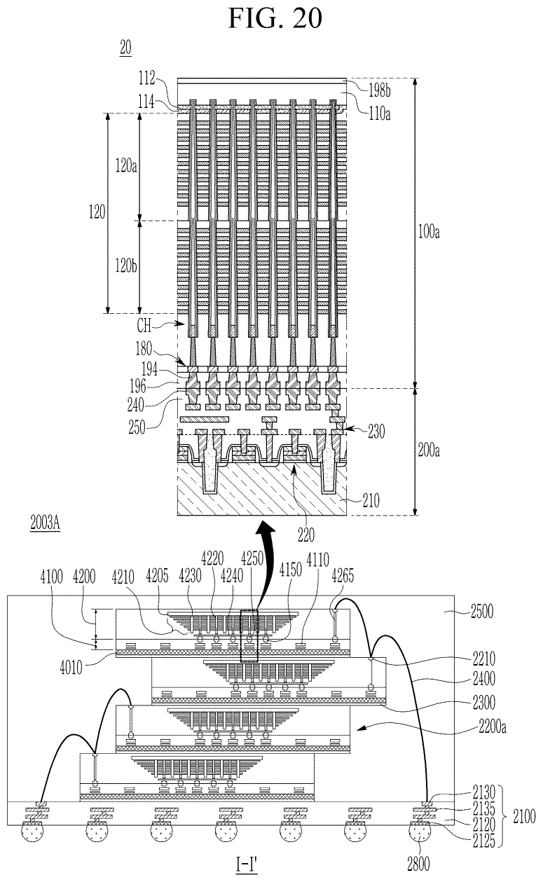

For example, the circuit region 200a and the cell region 100a may be portions corresponding to a first structure 1100F and a second structure 1100S of a semiconductor device 1100 included in an electronic system 1000 illustrated in FIG. 17, respectively. For example, the circuit region 200a and the cell region 100a may be regions including a first structure 4100 and a second structure 4200 of a semiconductor chip 2200a illustrated in FIG. 20, respectively.

An example of an electronic system including the semiconductor device will be described in detail below.

FIG. 17 is a view schematically illustrating an electronic system including a semiconductor device according to an embodiment.

Referring to FIG. 17, an electronic system 1000 according to an embodiment includes a semiconductor device 1100 and a controller 1200 (e.g., a controller circuit) electrically connected to the semiconductor device 1100. The electronic system 1000 may be a storage device including one or a plurality of semiconductor devices 1100 or an electronic device including the storage device. For example, the electronic system 1000 may be a solid-state drive (SSD) device, a universal serial bus (USB), a computing system, a medical device, or a communication device including one or a plurality of semiconductor devices 1100.

The semiconductor device 1100 may be a non-volatile memory device, and for example, may be a NAND flash memory device described with reference to FIG. 1 to FIG. 16. The semiconductor device 1100 may include a first structure 1100F and a second structure 1100S on the first structure 1100F. In some embodiments, the first structure 1100F may be next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to an embodiment.

In an embodiment, the lower transistors LT1 and LT2 may include a ground selection transistor, and the upper transistors UT1 and UT2 may include a string selection transistor. The first and second gate lower lines LL1 and LL2 may be gate lines of the lower transistors LT1 and LT2, respectively. The word line WL may be a gate line of the memory cell transistor MCT, and the gate upper lines UL1 and UL2 may be gate lines of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 extending to the second structure 1100S within the first structure 1100F. The bit line BL may be electrically connected to the page buffer 1120 through a second connection wiring 1125 extending to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending to the second structure 1100S within the first structure 1100F.

The controller 1200 may include a processor 1210, a NAND controller 1220 (e.g., a controller circuit), and a host interface 1230 (e.g., an interface circuit). According to an embodiment, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or so on may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

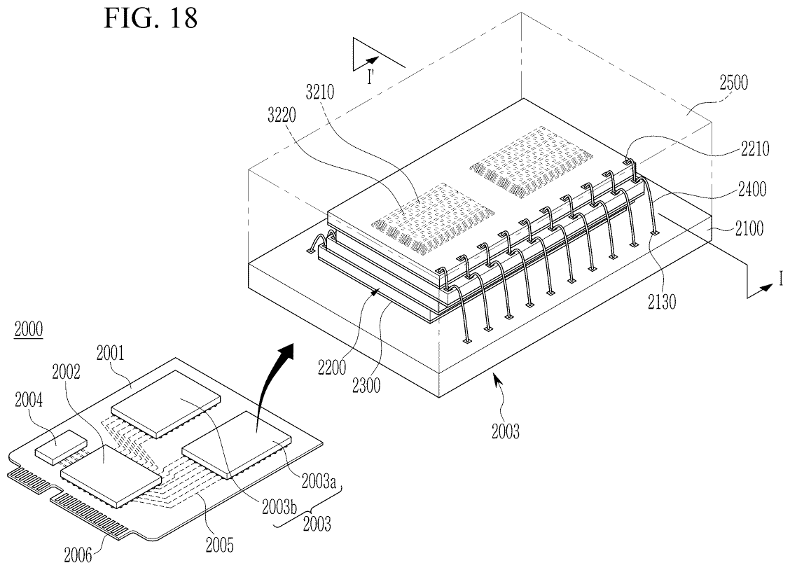

FIG. 18 is a perspective view schematically illustrating an electronic system including a semiconductor device according to an embodiment.

Referring to FIG. 18, an electronic system 2000 according to an embodiment may include a main substrate 2001, a controller 2002 (e.g., a controller circuit) disposed on the main substrate 2001, one or more semiconductor packages 2003, and a DRAM 2004. The semiconductor package 2003 and the DRAM 2004 may be connected to the controller 2002 through a wiring pattern 2005 at the main substrate 2001.

The main substrate 2001 may include a connector 2006 including a plurality of pins coupled to the external host. A number and an arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), and an M-Phy for a universal flash storage (UFS). In an embodiment, the electronic system 2000 may operate by power supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chip 2200 on the package substrate 2100, an adhesive layer 2300 at a lower surface of each semiconductor chip 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 17. Each semiconductor chip 2200 may include a gate stacking structure 3210 and a channel structure 3220. The semiconductor chip 2200 may include the semiconductor device described with reference to FIG. 1 to FIG. 16.

In an embodiment, the connection structure 2400 may be a bonding wire electrically connecting the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to a package upper pad 2130 of the package substrate 2100. According to an embodiment, in each of the first and second semiconductor packages 2003a and 2003b, the semiconductor chips 2200 may be electrically connected to each other by a connection structure including a through silicon via (TSV) instead of the connection structure 2400 using the bonding wire type.

In an embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring at the interposer substrate.

FIG. 19 and FIG. 20 are cross-sectional views schematically illustrating semiconductor packages according to embodiments, respectively. FIG. 19 and FIG. 20 respectively illustrate embodiments of the semiconductor package 2003 of FIG. 18, and conceptually illustrate a region obtained by cutting the semiconductor package 2003 of FIG. 18 along a line I-I′.

Referring to FIG. 19, in the semiconductor package 2003, the package substrate 2100 may be a printed circuit board. The package substrate 2100 may include a package substrate body portion 2120, a package upper pad 2130 at an upper surface of the package substrate body portion 2120, a package lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to a wiring pattern 2005 of the main substrate 2001 of the electronic system 2000, as illustrated in FIG. 18, through a conductive connection portion 2800.

The semiconductor chip 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 on the common source line 3205, a channel structure 3220 and a separation structure 3230 passing through the gate stacking structure 3210, a bit line 3240 electrically connected to the channel structure 3220, and a gate connection wiring electrically connected to a word line WL (refer to FIG. 17) of the gate stacking structure 3210.

In a semiconductor chip 2200 or a semiconductor device according to an embodiment, an integration degree of the semiconductor chip 2200 or the semiconductor device may be increased due to a separation insulator 214 and adjacent contacts 234a and 234b in contact with the separation insulator 214.

Each of the semiconductor chips 2200 may include a through wiring 3245 that is electrically connected to a peripheral wiring 3110 of the first structure 3100 and extends into the second structure 3200. The through wiring 3245 may pass through the gate stacking structure 3210, and may be further provided at an outside of the gate stacking structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In an embodiment, in the semiconductor package 2003, a plurality of semiconductor chips 2200 may be electrically connected to each other by a connection structure 2400 having a bonding wire type. In some embodiments, the plurality of semiconductor chips 2200 or a plurality of portions constituting the plurality of semiconductor chips 2200 may be electrically connected by a connection structure including a through silicon via (TSV).

Referring to FIG. 20, in a semiconductor package 2003A, each semiconductor chip 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 passing through the gate stacking structure 4210, and a second bonding structure 4250 electrically connected to the channel structure 4220 and a word line WL (refer to FIG. 17) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In a semiconductor chip 2200a or a semiconductor device according to an embodiment, an integration degree of the semiconductor chip 2200a or the semiconductor device may be increased by a separation insulator (e.g., 214) and adjacent contacts (e.g., 234a and 234b) in contact with the separation insulator.

Each of the semiconductor chips 2200a may further include an input/output pad 2210 and an input/output connection wiring 4265 at a lower portion of the input/output pad 2210. The input/output connection wiring 4265 may be electrically connected to a part of the second bonding structure 4250.

In an embodiment, in the semiconductor package 2003A, a plurality of semiconductor chips 2200a may be electrically connected to each other by the connection structure 2400 having a bonding wire type. In some embodiments, the plurality of semiconductor chips 2200a or a plurality of portions constituting the plurality of semiconductor chips 2200a may be electrically connected by a connection structure including a through silicon via (TSV).

While some examples have been described in connection with some embodiments, it is to be understood that the disclosure is not limited to these embodiments, and that that the disclosure is intended to cover various modifications and equivalent arrangements included within the spirit and scope of the appended claims.

What is claimed is:

1. A semiconductor device, comprising:
a semiconductor substrate;
a transistor disposed on the semiconductor substrate, the transistor including a gate structure, and source and drain regions disposed at respective sides of the gate structure;
a first interlayer insulation layer disposed on the gate structure and the source and drain regions of the transistor;
a plurality of contacts that passes through the first interlayer insulation layer, where each of the contacts is electrically connected to a corresponding one of the source and drain regions; and
a separation insulator that passes through the first interlayer insulation layer and extends to an inside of the semiconductor substrate at a boundary of the transistor,
wherein the plurality of contacts include an adjacent contact that is adjacent to the separation insulator and is spaced apart from the gate structure, and the first interlayer insulation layer is interposed between the adjacent contact and the gate structure.

2. The semiconductor device of claim 1, wherein the separation insulator extends in a first direction in a plan view, and
the adjacent contact includes a first contact disposed at a first side of the separation insulator in a second direction that is transverse to the first direction, and a second contact disposed at a second side of the separation insulator opposite to the first side of the separation insulator in the second direction.

3. The semiconductor device of claim 1 further comprising a plurality of transistors including the transistor, and
the separation insulator separates the source and drain regions included in one of the plurality of transistors and the source and drain regions included in another one of the plurality of transistors.

4. The semiconductor device of claim 1, wherein the adjacent contact includes a self-align contact that is self-aligned by the separation insulator.

5. The semiconductor device of claim 1, wherein the plurality of contacts further includes a separated contact, and
a side surface of the separated contact is surrounded by the first interlayer insulation layer to be spaced apart from the separation insulator.

6. The semiconductor device of claim 1, wherein the separation insulator includes a material different from a material of the first interlayer insulation layer.

7. The semiconductor device of claim 1, further comprising:
a device separator disposed at a boundary of the transistor at a side of one surface of the semiconductor substrate adjacent to the first interlayer insulation layer,
wherein the separation insulator includes a material different from a material of the device separator.

8. The semiconductor device of claim 7, wherein the first interlayer insulation layer or the device separator includes silicon oxide, and
the separation insulator includes silicon nitride.

9. The semiconductor device of claim 1, further comprising:
a device separator disposed at a boundary of the transistor at a side of one surface of the semiconductor substrate adjacent to the first interlayer insulation layer,
wherein one surface of the device separator and one surface of the separation insulator closest to one surface of the first interlayer insulation layer opposite to the semiconductor substrate are at different heights, or
the other surface of the device separator and the other surface of the separation insulator inside the semiconductor substrate are at different heights.

10. The semiconductor device of claim 1, wherein the separation insulator includes a first portion that passes through the first interlayer insulation layer, and a second portion inside the semiconductor substrate, and
a height of the second portion is greater than a width of the separation insulator.

11. The semiconductor device of claim 1, wherein the separation insulator includes a first portion that passes through the first interlayer insulation layer, and a second portion inside the semiconductor substrate, and
a height of the second portion is greater than a thickness of the gate structure.

12. The semiconductor device of claim 1, wherein the separation insulator includes a recess portion at a side surface of the separation insulator adjacent to one surface of the first interlayer insulation layer opposite to the semiconductor substrate.

13. The semiconductor device of claim 1, further comprising:
a high voltage transistor having an operating voltage higher than an operating voltage of the transistor; and
a device separator disposed at boundaries of the transistor and the high voltage transistor at a side of one surface of the semiconductor substrate adjacent to the first interlayer insulation layer,
wherein the separation insulator is disposed at the boundary of the transistor.

14. The semiconductor device of claim 1, further comprising:
a separating buffer layer disposed between the separation insulator and the semiconductor substrate, the separating buffer layer including a material different from a material of the separation insulator.

15. The semiconductor device of claim 1, wherein the semiconductor device comprises a circuit region including the semiconductor substrate and the transistor, and a cell region including a memory cell structure disposed on the circuit region, and
the transistor has a planar structure.

16. A semiconductor device, comprising:
a semiconductor substrate;
first and second transistors disposed on the semiconductor substrate, each of the transistors including a gate structure, and source and drain regions disposed at respective sides of the gate structure;
a device separator disposed in part of the semiconductor substrate;
a first interlayer insulation layer disposed on the gate structure and the source and drain regions of each the transistors, and the device separator; and
a separation insulator that passes through the first interlayer insulation layer and extends to an inside of the semiconductor substrate,
wherein the second transistor has an operating voltage higher than an operating voltage of the first transistor, and
the device separator and the separation insulator are disposed at a boundary of the first transistor, and the device separator is disposed at a boundary of the second transistor.

17. The semiconductor device of claim 16, further comprising:
a plurality of contacts that pass through the first interlayer insulation layer, where each of the contacts is electrically connected to a corresponding one of the source and drain regions,
wherein the plurality of contacts includes an adjacent contact that is adjacent to the separation insulator and is self-aligned by the separation insulator.

18. The semiconductor device of claim 16, wherein the separation insulator includes a material different from a material of the device separator.

19. The semiconductor device of claim 16, wherein one surface of the device separator and one surface of the separation insulator closest to one surface of the first interlayer insulation layer opposite to the semiconductor substrate are at different heights, or
the other surface of the device separator and the other surface of the separation insulator inside the semiconductor substrate are at different heights.

20. An electronic system, comprising:
a main substrate;
a semiconductor device disposed on the main substrate; and
a controller electrically disposed on the main substrate to be connected to the semiconductor device,
the semiconductor device comprises:
a semiconductor substrate;
a transistor disposed on the semiconductor substrate, the transistor including a gate structure, and source and drain regions disposed at respective sides of the gate structure;
a first interlayer insulation layer disposed on the gate structure and the source and drain regions of the transistor;
a plurality of contacts that pass through the first interlayer insulation layer, wherein each of the contacts is electrically connected to a corresponding one of the source and drain regions of the transistor; and
a separation insulator that passes through the first interlayer insulation layer and extends to an inside of the semiconductor substrate at a boundary of the transistor,
wherein the plurality of contacts include an adjacent contact that is adjacent to the separation insulator and is spaced apart from the gate structure, wherein the first interlayer insulation layer is interposed between the adjacent contact and the gate structure.
